(19) United States
(12) Patent Application Publication
(10) Pub. No.: US 2023/0352910 A1
(43) Pub. Date: Nov. 2, 2023

(54) LIGHT EMITTING ELEMENT, LIGHT EMITTING ELEMENT UNIT, ELECTRONIC DEVICE, LIGHT EMITTING DEVICE, SENSING DEVICE, AND COMMUNICATION DEVICE

(71) Applicant: Sony Group Corporation, Tokyo (JP)

(72) Inventors: Tatsushi HAMAGUCHI, Tokyo (JP); Masamichi ITO, Tokyo (JP); Mikihiro YOKOZEKI, Tokyo (JP); Rintaro KODA, Tokyo (JP)

(21) Appl. No.: 17/800,678

(22) PCT Filed: Feb. 22, 2021
(86) PCT No.: PCT/JP2021/006528

§ 371 Date: Aug. 18, 2022

(30) Foreign Application Priority Data
Mar. 27, 2020 (JP) 2020-057803

(51) Int. Cl. H01S 5/183; G01S 7/481

(52) U.S. Cl. CPC H01S 5/18361; G01S 7/4814

(57) ABSTRACT

A light emitting element according to the present disclosure includes: a laminated structure 20 in which a first compound semiconductor layer 21, an active layer 23, and a second compound semiconductor layer 22 are laminated; a first light reflecting layer 41 formed on a first surface side of the first compound semiconductor layer 21; a second light reflecting layer 42 formed on a second surface side of the second compound semiconductor layer 22; a first electrode 31 electrically connected to the first compound semiconductor layer 21; and a second electrode 32 electrically connected to the second compound semiconductor layer 22, a current confinement region 52 that controls an inflow of a current to the active layer 23 is provided, and when an axis in a thickness direction of the laminated structure 20 passing through a center of a current injection region 51 surrounded by the current confinement region 52 is defined as a Z axis, a direction orthogonal to the Z axis is defined as an X direction, and a direction orthogonal to the X direction and the Z axis is defined as a Y direction, the current injection region 51 has an elongated planar shape in which a longitudinal direction extends in the Y direction.

### TECHNICAL FIELD

The present disclosure relates to a light emitting element, more specifically, a light emitting element including a surface light emitting laser element (VCSEL), a light emitting element unit including the light emitting element, an electronic device, a light emitting device, a sensing device, and a communication device.

### BACKGROUND ART

For example, in a light emitting element including a surface light emitting laser element disclosed in WO 2018/083877 A1, laser oscillation occurs by causing laser light to resonate between two light reflecting layers (distributed Bragg reflector layer (DBR layer)). Further, in a surface light emitting laser element having a laminated structure in which an n-type compound semiconductor layer (first compound semiconductor layer), an active layer (light emitting layer) including a compound semiconductor, and a p-type compound semiconductor layer (second compound semiconductor layer) are laminated, a second electrode including a transparent conductive material is formed on the p-type compound semiconductor layer, and a second light reflecting layer is formed on the second electrode. In addition, a first light reflecting layer and a first electrode are formed on the n-type compound semiconductor layer (on the exposed surface of the substrate in a case where the n-type compound semiconductor layer is formed on the conductive substrate). Note that, in the present specification, the concept “above” may refer to a direction away from the active layer with respect to the active layer, the concept “below” may refer to a direction toward the active layer with respect to the active layer, and the concepts “convex” and “concave” may refer to the active layer. In addition, the orthographic projection image is an orthographic projection image on a laminated structure (as will be described later).

In the light emitting element, high straightness, that is, a narrow emission angle (radiation angle), is often required for the laser light to be emitted. As the emission angle is narrower, the ratio of the laser light leaking to the outside when the laser light is coupled to another optical system is reduced, and the coupling efficiency is increased. In addition, the optical system to be used can also be small and simplified, and it becomes easy to irradiate a distant place without an external optical system such as a lens. Furthermore, when the emitted laser light is condensed, the depth of focus is deep, and thus it is possible to alleviate requirements on positional accuracy and the like of various components.

### CITATION LIST

### Patent Document

Patent Literature 1: WO 2018/083877 A1

### SUMMARY OF THE INVENTION

### Problems to be Solved by the Invention

However, in a case of obtaining a light emitting element having high straightness, it is necessary to effectively expand the confinement region optically and electrically. In the technology disclosed in WO 2018/083877 A1 described above, the first light reflecting layer has a concave mirror structure, and accordingly, a light field with reduced lateral spread is positioned in an element region (as will be described later) to obtain laser oscillation. Then, low power consumption is realized by confining light in a narrower region. However, a light confinement region is wide. Therefore, in some cases, the emission angle becomes large, the far field pattern (FFP) becomes, for example, several degrees, and a requirement such as a narrow emission angle is not satisfied. In addition, when the light emitted from the light emitting element itself has a certain shape (figures, patterns, and the like), the configuration and structure of an electronic device or the like including such a light emitting element can be simplified.

Therefore, a first object of the present disclosure is to provide a light emitting element having a narrow emission angle (radiation angle) and a light emitting element unit including the light emitting element. In addition, a second object of the present disclosure is to provide a light emitting element in which emitted light itself has a certain shape. Furthermore, an object is to provide an electronic device, a light emitting device, a sensing device, and a communication device.

### Solutions to Problems

There is provided a light emitting element according to a first aspect or a second aspect of the present disclosure for achieving the first object or the second object described above, the light emitting element including:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer, in which
a current confinement region that controls an inflow of a current to the active layer is provided.

In addition, in the light emitting element according to the first aspect of the present disclosure, when an axis in a thickness direction of the laminated structure passing through a center of a current injection region surrounded by the current confinement region is defined as a Z axis, a direction orthogonal to the Z axis is defined as an X direction, and a direction orthogonal to the X direction and the Z axis is defined as a Y direction, the current injection region has an elongated planar shape in which a longitudinal direction extends in the Y direction.

In addition, in the light emitting element according to the second aspect of the present disclosure, a planar shape of the current injection region surrounded by the current confinement region includes at least one type of shape selected from a group consisting of an annular shape, a partially cut annular shape, a shape surrounded by a curve, a shape surrounded by a plurality of line segments, and a shape surrounded by a curve and a line segment.

There is provided a light emitting element unit of the present disclosure for achieving the first object described above, which is a light emitting element unit including a plurality of light emitting elements,
each of the light emitting elements includes the light emitting element according to the first aspect of the present disclosure, and
the plurality of light emitting elements is arranged apart from each other in the X direction.

There is provided an electronic device or a light emitting device of the present disclosure including: the light emitting element according to the first aspect and the second aspect of the present disclosure or the light emitting element unit of the present disclosure.

There is provided a sensing device of the present disclosure including:
a light exit device including the light emitting element according to the first aspect and the second aspect of the present disclosure or the light emitting element unit of the present disclosure; and
a light receiving device that receives light emitted from the light exit device.

There is provided a communication device of the present disclosure including:
a light exit device including a plurality of types of the light emitting elements according to the second aspect of the present disclosure; and
a light receiving device that receives light emitted from the light exit device.

### BRIEF DESCRIPTION OF DRAWINGS

FIG. 1 is a schematic partial end view of a light emitting element of Example 1.

(A) of FIG. 2 is a view schematically illustrating an arrangement state of a current injection region, a current confinement region, and a second electrode constituting the light emitting element of Example 1, and (B) and (C) of FIG. 2 are schematic partial end views of the light emitting element of Example 1 along arrows B-B and arrows C-C in (A) of FIG. 2.

(A), (B), and (C) of FIG. 3 are substantially the same as (A), (B), and (C) of FIG. 2, and are views in which various parameters are written.

FIG. 4 is a schematic partial end view of Modification Example-1 of the light emitting element of Example 1.

FIG. 5 is a schematic partial end view of Modification Example-2 of the light emitting element of Example 1.

FIG. 6 is a schematic partial end view of Modification Example-3 of the light emitting element of Example 1.

FIG. 7 is a schematic partial end view of Modification Example-4 of the light emitting element of Example 1.

FIG. 8 is a view schematically illustrating an arrangement state of a current injection region, a current confinement region, and a second electrode constituting a light emitting element of Example 2.

FIG. 9 is a view schematically illustrating an arrangement state of the current injection region, the current confinement region, and the second electrode constituting the light emitting element of Example 2.

(A) of FIG. 10 is a view schematically illustrating an arrangement state of a current injection region, a current confinement region, and a second electrode constituting Modification Example-1 of the light emitting element of Example 2, and (B) and (C) of FIG. 10 are schematic partial end views of Modification Example-1 of the light emitting element of Example 2 along arrows B-B and arrows C-C in (A) of FIG. 10.

(A) of FIG. 11 is a view schematically illustrating an arrangement state of a current injection region, a current confinement region, and a second electrode constituting Modification Example-2 of the light emitting element of Example 2, and (B) of FIG. 11 is a schematic partial end view of Modification Example-2 of the light emitting element of Example 2 along arrows B-B in (A) of FIG. 11.

FIG. 12 is a schematic partial end view of a light emitting element of Example 3.

FIGS. 13A and 13B are views schematically illustrating an arrangement state of a current injection region, a current confinement region, and a second electrode in a light emitting element constituting a light emitting element unit of Example 4.

FIG. 14 is a schematic partial end view of the light emitting element unit of Example 4.

FIG. 15 is a schematic partial end view of Modification Example-1 of the light emitting element unit of Example 4.

FIG. 16 is a schematic partial end view of a light emitting element of Example 5.

(A), (B), (C), and (D) of FIG. 17 are views schematically illustrating an arrangement state of a current injection region, a current confinement region, and a second electrode constituting the light emitting element of Example 5.

(A) of FIG. 18 is a view schematically illustrating an arrangement state of the current injection region, the current confinement region, and the second electrode constituting the light emitting element of Example 5, and (B) of FIG. 18 is a view schematically illustrating an arrangement state of the current injection region and the current confinement region constituting the light emitting element of Example 5.

(A), (B), (C), (D), and (E) of FIG. 19 are views schematically illustrating a planar shape of the current injection region constituting the light emitting element of Example 5.

FIG. 20 is a schematic partial end view of a light emitting element of Example 7.

FIGS. 21A and 21B are schematic partial end views of a laminated structure and the like for describing a method for manufacturing the light emitting element of Example 1.

FIG. 22 is a schematic partial end view of the laminated structure and the like for describing the method for manufacturing the light emitting element of Example 1, continuing from FIG. 21B.

FIG. 23 is a schematic partial end view of the laminated structure and the like for describing the method for manufacturing the light emitting element of Example 1, continuing from FIG. 22.

FIGS. 24A, 24B, and 24C are schematic partial end views of a first compound semiconductor layer and the like for describing the method for manufacturing the light emitting element of Example 1, continuing from FIG. 23.

FIGS. 25A, 25B, and 25C are schematic partial end views of the laminated structure and the like for describing the method for manufacturing the light emitting element of Example 3.

FIGS. 26A, 26B, and 26C are schematic partial end views of the laminated structure and the like for describing the method for manufacturing the light emitting element of Example 3.

FIGS. 27A and 27B are schematic partial end views of the laminated structure and the like for describing the method for manufacturing the light emitting element of Example 3, continuing from FIG. 25C.

FIG. 28 is a schematic partial sectional view of the light emitting element of Example 7, and a view in which two longitudinal modes of a longitudinal mode A and a longitudinal mode B are superimposed.

FIGS. 29A and 29B are conceptual diagrams schematically illustrating a longitudinal mode in a gain spectrum determined by an active layer.

### MODE FOR CARRYING OUT THE INVENTION

Hereinafter, the present disclosure will be described on the basis of examples with reference to the drawings, but the present disclosure is not limited to the examples, and various numerical values and materials in the examples are examples. Note that the description will be given in the following order.
1. General description of light emitting element according to first and second aspects of present disclosure, light emitting element unit of present disclosure, and the like
2. Example 1 (light emitting element according to first aspect of present disclosure)
3. Example 2 (modification of Example 1)
4. Example 3 (modification of Examples 1 and 2)
5. Example 4 (light emitting element unit of present disclosure)
6. Example 5 (light emitting element according to second aspect of present disclosure)
7. Example 6 (modification of Examples 1 to 5)
8. Example 7 (modification of Examples 1 to 6)
9. Example 8 (modification of Example 7)
10. Example 9 (another modification of Example 7)
11. Example 10 (application of light emitting element according to first and second aspects of present disclosure, and light emitting element unit of present disclosure)
12. Example 11 (application of light emitting element according to first and second aspects of present disclosure, and light emitting element unit of present disclosure)
13. Example 12 (application of light emitting element according to first and second aspects of present disclosure, and light emitting element unit of present disclosure)
14. Others

<General Description of Light Emitting Element According to First and Second Aspects of Present Disclosure, Light Emitting Element Unit of Present Disclosure, and the Like>

In the light emitting element according to the first aspect of the present disclosure, when a width of the current injection region along the Y direction is L_{max-Y} and a width along the X direction is L_{min-X},

L_{max-Y}/L_{min-X}≥3

may be satisfied, and preferably,

L_{max-Y}/L_{min-X}≥20

may be satisfied. Note that, in a case where there is variation, fluctuation, or change in the width L_{max-Y} along the Y direction and the width L_{min-X} along the X direction of the current injection region, or in a case where the width L_{min-X} is changed, the averages of the widths is only required to be L_{max-Y} and L_{min-X}. The same applies below.

In the light emitting element according to the first aspect of the present disclosure including the preferable aspect described above, the first light reflecting layer may have a convex shape toward a direction away from the active layer, and the second light reflecting layer may have a flat shape. Then, in this case, a resonator length L_{OR} along the Z axis is not limited, and examples thereof include 1×10⁻⁵ m≤L_{OR}≤×10⁻⁵ m.

Here, with reference to the second surface of the first compound semiconductor layer, the first part of a base surface (as will be described later) on which the first light reflecting layer is formed has an upward convex shape. A part outside the first part of the base surface is referred to as a second part, and the second part is flat or concave toward the second surface with reference to the second surface of the first compound semiconductor layer. The second part of the base surface may also be referred to as a peripheral region. The extending portion of the first light reflecting layer may be formed in the second part of the base surface, or the first light reflecting layer may not be formed in the second part.

The shape (figure) drawn by the first part or the second part of the base surface when the first part or the second part of the base surface is cut along the XZ virtual plane may be a part of a circle, a part of a parabola, a part of a sine curve, a part of an ellipse, or a part of a catenary curve. The shape (figure) may not be strictly a part of a circle, may not be strictly a part of a parabola, may not be strictly a part of a sine curve, may not be strictly a part of an ellipse, and may not be strictly a part of a catenary curve. In other words, a case of being substantially a part of a circle, a case of being substantially a part of a parabola, a case of being substantially a part of a sine curve, a case of being substantially a part of an ellipse, and a case of being substantially a part of a catenary curve are also included in the case of “the shape is a part of a circle, a part of a parabola, a part of a sine curve, substantially a part of an ellipse, or substantially a part of a catenary curve.” A part of these curves may be replaced by a line segment. The shape (figure) drawn by the base surface can be obtained by measuring the shape of the base surface with a measuring instrument and analyzing the obtained data on the basis of the least square method.

In addition, the shape (figure) drawn by the top portion when the first part of the base surface is cut along the YZ virtual plane can be a line segment, a part of a circle extending from one end and the other end of the line segment, a part of a parabola, a part of a sine curve, a part of an ellipse, and a part of a catenary curve. A line segment when the flat second part of the base surface is cut along the YZ virtual plane and a part of the line segment of a shape (figure) drawn by the top when the first part of the base surface is cut along the YZ virtual plane may be parallel to each other.

It is desirable that a radius of curvature R₁ of the center portion of the shape drawn by the convex part when the first part of the base surface is cut along the XZ virtual plane satisfy 1.5×10⁻⁵ m≤R₁≤1×10⁻³ m, and preferably, 3×10⁻⁵ m≤R₁≤1.5×10⁻⁴ m.

The second part of the base surface may be flat or may be concave toward the second surface of the first compound semiconductor layer. In the latter case, it is desirable that a radius of curvature R₂ of the center portion of the second part of the base surface when cut along the XZ virtual plane be 1×10⁻⁶ m or more, preferably 3×10⁻⁶ m or more, and more preferably 5×10⁻⁶ m or more.

Here, it is desirable that the first part to the second part be differentiable each other. In other words, when the base surface is represented by z=f(x, y), the differential value on the base surface can be obtained by σz/σx=[σf(x, y)/σx]y and σz/σy=[σf(x, y)/σy]_{X}. The term “smooth” is an analytical term. For example, when the real variable function ƒ(x) is differentiable in a<x<b and f′ (x) is continuous, it can be said that the base surface is continuously differentiable in expression, and is expressed as being smooth. Then, a part where an inflection point exists in the base surface from the first part to the second part is a boundary between the first part and the second part.

The shape “from the peripheral portion of first part/second part to center portion” may be (A) “upward convex shape/downward convex shape,” (B) “continuing from upward convex shape/downward convex shape to line segment,” (C) “continuing from upward convex shape/upward convex shape to downward convex shape,” (D) “continuing from upward convex shape/upward convex shape to downward convex shape and line segment,” (E) “continuing from upward convex shape/line segment to downward convex shape,” and (F) “continuing from upward convex shape/line segment to downward convex shape and line segment.” Note that, in the light emitting element, the base surface may terminate at the center portion of the second part.

Furthermore, in the light emitting element according to the first aspect of the present disclosure including the preferable aspect described above, the planar shape of the first light reflecting layer may be a shape (approximate shape) approximating the planar shape of the current injection region.

Furthermore, in the light emitting element according to the first aspect of the present disclosure including the preferable aspect described above, an emission angle θ_{Y} of the light in the YZ virtual plane may be 2 degrees or less. The emission angle of light in the XZ virtual plane is represented by θ_{X}. The FFP of the light emitting element is only required to be obtained, and the emission angle θ_{Y} is only required to be obtained by a known method from the FFP on the YZ virtual plane when it is assumed that the light emitting element is cut along the YZ virtual plane, or the emission angle θ_{X} is only required to be obtained by a known method from the FFP on the XZ virtual plane when it is assumed that the light emitting element is cut along the XZ virtual plane. The emission angle is an emission angle when a light intensity that is the full width at half maximum of the maximum light intensity in the light beam distribution of the FFP is obtained.

Furthermore, in the light emitting element according to the first aspect of the present disclosure including the preferable aspect described above, the planar shape of the current injection region may be an oval shape. Here, the oval shape is a shape including two parallel line segments, a semicircle connecting one end portions of the two line segments, and a semicircle connecting the other end portions of the two line segments. The two line segments can also be replaced with two curves.

Alternatively, in the light emitting element according to the first aspect of the present disclosure including the preferable aspect described above, the planar shape of the current injection region may be a rectangular shape. Then, in such a configuration, a side surface including a side parallel to the X direction of the current injection region may be in contact with the current confinement region, an end surface including a side parallel to the X direction of the current injection region may be in contact with, for example, the atmosphere, or an end surface including a side parallel to the X direction of the current injection region may be in contact with a layer (laminated film) on which the first dielectric layer and the second dielectric layer are alternately arranged in the Y direction. The outer surface of the laminated film may be in contact with the current confinement region, or may be in contact with the atmosphere, for example. Furthermore, in these configurations, the side parallel to the Y direction of the current injection region may include a line segment or a curve.

In the light emitting element according to the second aspect of the present disclosure, the planar shape of the current injection region may include characters or figures.

In the light emitting element unit of the present disclosure, when a width of the current injection region along the Y direction in each light emitting element is L_{max-Y} and a width along the X direction is L_{min-X},

L_{max-Y}/L_{min-X}≥3

may be satisfied, and preferably,

L_{max-Y}/L_{min-X}≥20

may be satisfied, and when an array pitch of the plurality of light emitting elements along the X direction is P_{X},

P_{X}/L_{min-X}≥1.5

may be satisfied, and preferably,

P_{X}/L_{min-X}≥5

may be satisfied.

In the light emitting element unit of the present disclosure including the preferable aspect described above,
in the entire light emitting element unit,
an emission angle θ_{Y}′ of light in the YZ virtual plane may be 2 degrees or less, and
an emission angle θ_{X}′ of light in the XZ virtual plane may be 0.1 degrees or less.

Furthermore, in the light emitting element unit of the present disclosure including the preferable aspect described above, the first electrode may be common to the plurality of light emitting elements, and the second electrode may be individually provided in each light emitting element, or the first electrode may be common to the plurality of light emitting elements, and the second electrode may be common to the plurality of light emitting elements.

Furthermore, in the light emitting element of the present disclosure including the preferable aspect and configuration described above, a plurality of groove portions extending in one direction (for example, a first direction) may be formed in the second electrode in order to control the polarization state of the light emitted from the light emitting element. Specifically, the plurality of groove portions extending in the first direction is included in a virtual plane (in an XY virtual plane) orthogonal to the thickness direction of the second electrode. In a case where a formation pitch P₀ of the groove portion is significantly smaller than a wavelength λ₀ of the incident light, the light vibrating on a plane parallel to the extending direction (first direction) of the groove portion is selectively reflected and absorbed in the groove portion. Here, the distance between the line portion and the line portion of the groove portion (the distance between the space portions along the second direction) is set as the formation pitch P₀ of the groove portion. Then, the light (electromagnetic waves) reaching the groove portion includes a longitudinally polarized component and a laterally polarized component, but the electromagnetic waves having passed through the groove portion become linearly polarized light in which the longitudinally polarized component is dominant. Here, in the case of considering focusing on the visible light wavelength range, in a case where the formation pitch P₀ of the groove portion is significantly smaller than an effective wavelength λ_{eff} of light (electromagnetic waves) incident on the groove portion, polarized components biased to a plane parallel to the first direction are reflected or absorbed by the surface of the groove portion. On the other hand, when light having a polarized component biased to a plane parallel to the second direction is incident on the groove portion, the electric field (light) propagating through the surface of the groove portion passes (is emitted) with the same wavelength as the incident wavelength from the back surface of the groove portion, and the same polarization orientation. Here, when the average refractive index obtained on the basis of the substance present in the space portion is nₐᵥₑ, the effective wavelength λ_{eff} is expressed by (λ₀/nₐᵥₑ). The average refractive index nₐᵥₑ is a value obtained by adding the product of the refractive index and the volume of the substance present in the space portion and dividing the product by the volume of the space portion. In a case where the value of the wavelength λ₀ is constant, the value of the effective wavelength λ_{eff} increases as the value of nₐᵥₑ decreases, and thus the value of the formation pitch P₀ can be increased. In addition, the larger the value of nₐᵥₑ, the lower the light transmittance and the lower the extinction ratio in the groove portion.

In the light emitting elements (hereinafter referred to as “light emitting element and the like in the present disclosure”) according to the first and second aspects of the present disclosure including the preferable aspect and configuration described above, the laminated structure may include at least one type of material selected from the group consisting of a GaN-based compound semiconductor, an InP-based compound semiconductor, and a GaAs-based compound semiconductor. Specifically, examples of the laminated structure include (a) a configuration including a GaN-based compound semiconductor, (b) a configuration including an InP-based compound semiconductor, (c) a configuration including a GaAs-based compound semiconductor, (d) a configuration including a GaN-based compound semiconductor and an InP-based compound semiconductor, (e) a configuration including a GaN-based compound semiconductor and a GaAs-based compound semiconductor, (f) a configuration including an InP-based compound semiconductor and a GaAs-based compound semiconductor, and (g) a configuration including a GaN-based compound semiconductor, an InP-based compound semiconductor, and a GaAs-based compound semiconductor.

In the light emitting element and the like of the present disclosure, the value of the thermal conductivity of the laminated structure may be higher than the value of the thermal conductivity of the first light reflecting layer. The value of the thermal conductivity of the dielectric material constituting the first light reflecting layer is generally approximately 10 watts/(m·K) or less. On the other hand, the value of the thermal conductivity of the GaN-based compound semiconductor constituting the laminated structure is approximately 50 watts/(m·K) to approximately 100 watts/(m·K) or 100 watts/(m·K) or less.

In the light emitting element and the like of the present disclosure, in a case where various compound semiconductor layers (including a compound semiconductor substrate) are present between the active layer and the first light reflecting layer, materials constituting the various compound semiconductor layers (including a compound semiconductor substrate) preferably have no modulation of the refractive index of 10% or more (there is no refractive index difference of 10% or more on the basis of the average refractive index of the laminated structure), and accordingly, it is possible to suppress occurrence of disturbance of the light field in the resonator.

The light emitting element and the like of the present disclosure may constitute a surface light emitting laser element (vertical-cavity surface-emitting laser (VCSEL)) that emits laser light via the first light reflecting layer, or may also constitute a surface light emitting laser element that emits laser light via the second light reflecting layer. In some cases, a light emitting element manufacturing substrate (as will be described later) may be removed.

In the light emitting element and the like of the present disclosure, specifically, as described above, the laminated structure may include, for example, an AlInGaN-based compound semiconductor. Here, more specific examples of the AlInGaN-based compound semiconductor include GaN, AlGaN, InGaN, and AlInGaN. Furthermore, these compound semiconductors may contain a boron (B) atom, a thallium (Tl) atom, an arsenic (As) atom, a phosphorus (P) atom, or an antimony (Sb) atom as desired. The active layer desirably has a quantum well structure. Specifically, a single quantum well structure (SQW structure) may be provided, or a multiple quantum well structure (MQW structure) may be provided. The active layer having a quantum well structure has a structure in which at least one well layer and one barrier layer are laminated, and examples of the combination (the compound semiconductor constituting the well layer and the compound semiconductor constituting the barrier layer) include (In_{Y}Ga_{(1-y)}N, GaN), (In_{Y}Ga_{(1-y)}N, In_{z}Ga_{(1-z)}N) (where y>z), and (In_{Y}Ga_{(1-y)}N, AlGaN). The first compound semiconductor layer can include a first conductivity type (for example, n-type) compound semiconductor, and the second compound semiconductor layer can include a compound semiconductor of a second conductivity type (for example, p-type) which is different from the first conductivity type. The first compound semiconductor layer and the second compound semiconductor layer are also referred to as a first cladding layer and a second cladding layer. The first compound semiconductor layer and the second compound semiconductor layer may be a single structure layer, a multi-layer structure layer, or a superlattice structure layer. Furthermore, a layer including a composition gradient layer and a concentration gradient layer can also be used.

Alternatively, examples of the group III atoms constituting the laminated structure include gallium (Ga), indium (In), and aluminum (Al), and examples of the group V atoms constituting the laminated structure include arsenic (As), phosphorus (P), antimony (Sb), and nitrogen (N). Specific examples thereof include AlAs, GaAs, AlGaAs, AlP, GaP, GaInP, AlInP, AlGaInP, AlAsP, GaAsP, AlGaAsP, AlInAsP, GaInAsP, AlInAs, GaInAs, AlGaInAs, AlAsSb, GaAsSb, AlGaAsSb, AlN, GaN, InN, AlGaN, GaNAs, and GaInNAs. Specific examples of the compound semiconductor constituting the active layer include GaAs, AlGaAs, GaInAs, GaInAsP, GaInP, GaSb, GaAsSb, GaN, InN, GaInN, GaInNAs, and GaInNAsSb.

Examples of the quantum well structure include a two-dimensional quantum well structure, a one-dimensional quantum well structure (quantum fine wire), and a zero-dimensional quantum well structure (quantum dot). Examples of a material constituting the quantum well include Si; Se; CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, and AgInSe₂ which are chalcopyrite-based compounds; a perovskite-based material; GaAs, GaP, InP, AlGaAs, InGaP, AlGaInP, InGaAsP, GaN, InAs, InGaAs, GaInNAs, GaSb, and GaAsSb which are group III-V compounds; CdSe, CdSeS, CdS, CdTe, In₂Se₃, In₂S₃, Bi₂Se₃, Bi₂S₃, ZnSe, ZnTe, ZnS, HgTe, HgS, PbSe, PbS, and TiO₂; and the like, but are not limited thereto.

The laminated structure is formed on the second surface of the light emitting element manufacturing substrate or formed on the second surface of the compound semiconductor substrate. Note that the second surface of the light emitting element manufacturing substrate or the compound semiconductor substrate opposes the first surface of the first compound semiconductor layer, and the first surface of the light emitting element manufacturing substrate or the compound semiconductor substrate opposes the second surface of the light emitting element manufacturing substrate or the compound semiconductor substrate. Examples of the light emitting element manufacturing substrate include a GaN substrate, a sapphire substrate, a GaAs substrate, a SiC substrate, an alumina substrate, a ZnS substrate, a ZnO substrate, an AlN substrate, a LiMgO substrate, a LiGaO₂ substrate, a MgAl₂O₄ substrate, an InP substrate, a Si substrate, and a substrate in which a base layer or a buffer layer is formed on the surface (main surface) of these substrates, but the use of a GaN substrate is preferable because of low defect density. Further, examples of the compound semiconductor substrate include a GaN substrate, an InP substrate, and a GaAs substrate. Although it is known that characteristics such as polarity/non-polarity/semi-polarity of a GaN substrate vary depending on a growth surface, any main surface (second surface) of the GaN substrate can be used for formation of a compound semiconductor layer. Furthermore, regarding the main surface of the GaN substrate, depending on the crystal structure (for example, a cubic crystal type, a hexagonal crystal type, or the like), a crystal plane orientation referred to as so-called A plane, B plane, C plane, R plane, M plane, N plane, S plane, or the like, or a plane in which these are shifted in a specific direction or the like can also be used. Examples of a method for forming various compound semiconductor layers constituting the light emitting element include, but are not limited to, an organic metal chemical vapor deposition method (metal organic-chemical vapor deposition method (MOCVD method) and metal organic-vapor phase epitaxy method (MOVPE method)), a molecular beam epitaxy method (MBE method), a hydride vapor phase epitaxy method (HVPE method) in which a halogen contributes to transport or reaction, an atomic layer deposition method (ALD method), a migration-enhanced epitaxy method (MEE method), a plasma-assisted physical vapor deposition method (PPD method), and the like.

The GaAs and InP materials also have a zinc blende structure. Examples of the main surface of the compound semiconductor substrate including these materials include surfaces shifted in a specific direction in addition to surfaces such as (100), (111)AB, (211)AB, and (311)AB. Note that “AB” means that the 90° off direction is different, and whether the main material of the surface is group III or group V is determined according to the off direction. By controlling these crystal plane orientation and film formation conditions, composition unevenness and dot shape can be controlled. As a film forming method, a film forming method such as an MBE method, an MOCVD method, an MEE method, or an ALD method is generally used as with the GaN-based method, but the film forming method is not limited to these methods.

Here, in the formation of the GaN-based compound semiconductor layer, examples of the organic gallium source gas in the MOCVD method include trimethylgallium (TMG) gas and triethylgallium (TEG) gas, and examples of the nitrogen source gas include ammonia gas and hydrazine gas. In formation of a GaN-based compound semiconductor layer having an n-type conductivity type, for example, silicon (Si) is only required to be added as an n-type impurity (n-type dopant), and in formation of a GaN-based compound semiconductor layer having a p-type conductivity type, for example, magnesium (Mg) is only required to be added as a p-type impurity (p-type dopant). In a case where aluminum (Al) or indium (In) is contained as a constituent atom of the GaN-based compound semiconductor layer, trimethylaluminum (TMA) gas may be used as an Al source, and trimethylindium (TMI) gas may be used as an In source. Furthermore, monosilane gas (SiH₄ gas) may be used as the Si source, and biscyclopentadienyl magnesium gas, methylcyclopentadienyl magnesium, or biscyclopentadienyl magnesium (Cp₂Mg) may be used as the Mg source. Note that examples of the n-type impurity (n-type dopant) include Ge, Se, Sn, C, Te, S, O, Pd, and Po in addition to Si, and examples of the p-type impurity (p-type dopant) include Zn, Cd, Be, Ca, Ba, C, Hg, and Sr in addition to Mg.

In a case where the laminated structure includes an InP-based compound semiconductor or a GaAs-based compound semiconductor, TMGa, TEGa, TMIn, TMAl, and the like, which are organic metal raw materials, are generally used as the group III raw material. Further, as the group V raw material, arsine gas (AsH₃ gas), phosphine gas (PH₃ gas), ammonia (NH₃), or the like is used. Note that, regarding the group V raw material, an organic metal raw material may be used, and examples thereof include tertiary-butylarsine (TBAs), tertiary-butylphosphine (TBP), dimethylhydrazine (DMHy), trimethylantimony (TMSb), and the like. These materials are effective in low-temperature growth because the materials decompose at low temperatures. As the n-type dopant, monosilane (SiH₄) is used as a Si source, and hydrogen selenide (H₂Se) or the like is used as a Se source. Further, dimethyl zinc (DMZn), biscyclopentadienyl magnesium (Cp₂Mg), and the like are used as the p-type dopant. As the dopant material, a material similar to a GaN-based material is a candidate.

The first surface of the first compound semiconductor layer may constitute a base surface. Alternatively, the compound semiconductor substrate (or the light emitting element manufacturing substrate) may be disposed between the first surface of the first compound semiconductor layer and the first light reflecting layer, and the base surface may include a surface of the compound semiconductor substrate (or the light emitting element manufacturing substrate), and in this case, for example, the compound semiconductor substrate may include a GaN substrate. As the GaN substrate, any of a polar substrate, a semi-polar substrate, and a non-polar substrate may be used. As the thickness of the compound semiconductor substrate, 5×10⁻⁵ m to 1×10⁻⁴ m can be exemplified, but the thickness is not limited to such a value. Alternatively, the base material may be disposed between the first surface of the first compound semiconductor layer and the first light reflecting layer, or the compound semiconductor substrate and the base material may be disposed between the first surface of the first compound semiconductor layer and the first light reflecting layer, and the base surface may include the surface of the base material. Examples of the material constituting the base material include transparent dielectric materials such as TiO₂, Ta₂O₅, and SiO₂, silicone-based resins, and epoxy-based resins.

In manufacturing the light emitting element and the like of the present disclosure, the light emitting element manufacturing substrate may be left, or the light emitting element manufacturing substrate may be removed after sequentially forming the active layer, the second compound semiconductor layer, the second electrode, and the second light reflecting layer on the first compound semiconductor layer. Specifically, the active layer, the second compound semiconductor layer, the second electrode, and the second light reflecting layer may be sequentially formed on the first compound semiconductor layer formed on the light emitting element manufacturing substrate, the second light reflecting layer may then be fixed to the support substrate, and then the light emitting element manufacturing substrate may be removed to expose the first compound semiconductor layer (the first surface of the first compound semiconductor layer). Regarding the removal of the light emitting element manufacturing substrate, the light emitting element manufacturing substrate can be removed by a wet etching method using an alkali aqueous solution such as a sodium hydroxide aqueous solution or a potassium hydroxide aqueous solution, an ammonia solution+a hydrogen peroxide solution, a sulfuric acid solution+a hydrogen peroxide solution, a hydrochloric acid solution+a hydrogen peroxide solution, a phosphoric acid solution+a hydrogen peroxide solution, or the like; a dry etching method such as a chemical mechanical polishing method (CMP method), a mechanical polishing method, a reactive ion etching (RIE) method, or the like; a lift-off method using a laser; or a combination thereof.

The support substrate for fixing the second light reflecting layer is only required to include, for example, various substrates exemplified as a light emitting element manufacturing substrate, or may include an insulating substrate including AlN or the like, a semiconductor substrate including Si, SiC, Ge or the like, a metal substrate, or an alloy substrate, but it is preferable to use a substrate having conductivity, or it is preferable to use a metal substrate or an alloy substrate from the viewpoint of mechanical characteristics, elastic deformation, plastic deformability, heat dissipation, and the like. The thickness of the support substrate can be, for example, 0.05 mm to 1 mm. As a method for fixing the second light reflecting layer to the support substrate, a known method such as a solder bonding method, a normal temperature bonding method, a bonding method using an adhesive tape, a bonding method using wax bonding, or a method using an adhesive can be used, but from the viewpoint of ensuring conductivity, it is desirable to employ a solder bonding method or a normal temperature bonding method. For example, in a case where a silicon semiconductor substrate which is a conductive substrate is used as a support substrate, it is desirable to adopt a method capable of bonding at a low temperature of 400° C. or lower in order to suppress warpage due to a difference in thermal expansion coefficient. When a GaN substrate is used as the support substrate, the bonding temperature may be 400° C. or higher.

In a case where the light emitting element manufacturing substrate is left, the first electrode is only required to be formed on the first surface opposing the second surface of the light emitting element manufacturing substrate, or is only required to be formed on the first surface opposing the second surface of the compound semiconductor substrate. Further, in a case where the light emitting element manufacturing substrate is not left, the first electrode is only required to be formed on the first surface of the first compound semiconductor layer constituting the laminated structure. In this case, since the first light reflecting layer is formed on the first surface of the first compound semiconductor layer, for example, the first electrode is only required to be formed so as to surround the first light reflecting layer. The first electrode desirably has a single-layer configuration or a multi-layer configuration including at least one type of metal (including an alloy) selected from the group consisting of, for example, gold (Au), silver (Ag), palladium (Pd), platinum (Pt), nickel (Ni), titanium (Ti), vanadium (V), tungsten (W), chromium (Cr), aluminum (Al), copper (Cu), zinc (Zn), tin (Sn), and indium (In). Specifically, for example, Ti/Au, Ti/Al, Ti/Al/Au, Ti/Pt/Au, Ni/Au, Ni/Au/Pt, Ni/Pt, Pd/Pt, and Ag/Pd can be exemplified. Note that the layer before “/” in the multi-layer configuration is positioned closer to the active layer side. The same applies below. The first electrode can be formed by, for example, a PVD method such as a vacuum deposition method or a sputtering method.

In a case where the first electrode is formed so as to surround the first light reflecting layer, the first light reflecting layer and the first electrode can be in contact with each other. Alternatively, the first light reflecting layer and the first electrode can be apart from each other. In some cases, a state where the first electrode is formed up to an edge portion of the first light reflecting layer and a state where the first light reflecting layer is formed up to an edge portion of the first electrode can be mentioned.

The second electrode may include a transparent conductive material. Examples of the transparent conductive material include: an indium-based transparent conductive material (specifically, for example, indium-tin oxide (including indium tin oxide (ITO), Sn-doped In₂O₃, crystalline ITO, and amorphous ITO), indium-zinc oxide (indium zinc oxide (IZO)), indium-gallium oxide (IGO), indium-doped gallium-zinc oxide (In-GaZnO₄ (IGZO)), IFO (F-doped In₂O₃), ITiO (Ti-doped In₂O₃), InSn, and InSnZnO); a tin-based transparent conductive material (specifically, for example, tin oxide (SnO_{X}), ATO (Sb-doped SnO₂), and FTO (F-doped SnO₂)); a zinc-based transparent conductive material (specifically, for example, zinc oxide (including ZnO, Al-doped ZnO (AZO), and B-doped ZnO), gallium-doped zinc oxide (GZO), AlMgZnO (aluminum oxide and magnesium oxide-doped zinc oxide)); NiO; and TiO_{X}. Alternatively, examples of the material constituting the second electrode include a transparent conductive film having gallium oxide, titanium oxide, niobium oxide, antimony oxide, nickel oxide, or the like as a base layer, and also include a transparent conductive material such as a spinel type oxide or an oxide having a YbFe₂O₄ structure. The second electrode can be formed by, for example, a PVD method such as a vacuum deposition method or a sputtering method. Alternatively, a low-resistance semiconductor layer can be used as the second electrode, and in this case, specifically, an n-type GaN-based compound semiconductor layer can also be used. Furthermore, in a case where the layer adjacent to the n-type GaN-based compound semiconductor layer is a p-type, the electric resistance of the interface can also be reduced by bonding both layers via a tunnel junction.

A first pad electrode and a second pad electrode may be provided on the first electrode and the second electrode in order to be electrically connected to an external electrode or circuit (hereinafter may be referred to as “external circuit or the like”). The pad electrode desirably has a single-layer configuration or a multi-layer configuration containing at least one type of metal selected from the group consisting of titanium (Ti), aluminum (Al), platinum (Pt), gold (Au), nickel (Ni), and palladium (Pd). Alternatively, the pad electrode may have a multi-layer configuration exemplified by a Ti/Pt/Au multi-layer configuration, a Ti/Au multi-layer configuration, a Ti/Pd/Au multi-layer configuration, a Ti/Pd/Au multi-layer configuration, a Ti/Ni/Au multi-layer configuration, and a Ti/Ni/Au/Cr/Au multi-layer configuration. In a case where the first electrode includes an Ag layer or an Ag/Pd layer, it is preferable to form a cover metal layer including, for example, Ni/TiW/Pd/TiW/Ni on the surface of the first electrode, and to form a pad electrode including, for example, a multi-layer configuration of Ti/Ni/Au or a multi-layer configuration of Ti/Ni/Au/Cr/Au on the cover metal layer.

The light reflecting layer (distributed Bragg reflector layer (DBR Layer)) constituting the first light reflecting layer and the second light reflecting layer includes, for example, a semiconductor multi-layer film or a dielectric multi-layer film. Examples of the dielectric material include oxides such as Si, Mg, Al, Hf, Nb, Zr, Sc, Ta, Ga, Zn, Y, B, and Ti, nitrides (for example, SiN_{X}, AlN_{X}, AlGaN_{X}, GaN_{X}, BN_{X}, and the like), fluorides, and the like. Specifically, SiO_{X}, TiO_{X}, NbO_{X}, ZrO_{X}, TaO_{X}, ZnO_{X}, AlO_{X}, HfO_{X}, SiN_{X}, AlN_{X}, and the like can be exemplified. Then, the light reflecting layer can be obtained by alternately laminating two or more types of dielectric films including dielectric materials having different refractive indexes among these dielectric materials. For example, a multi-layer film such as SiO_{X}/SiN_{Y}, SiO_{X}/TaO_{X}, SiO_{X}/NbO_{Y}, SiO_{X}/ZrO_{Y}, or SiO_{X}/AlN_{Y} is preferable. In order to obtain a desired light reflectance, a material constituting each dielectric film, a film thickness, the number of laminated layers, and the like is only required to be appropriately selected. The thickness of each dielectric film can be appropriately adjusted depending on the material to be used or the like, and is determined by the oscillation wavelength (emission wavelength) λ₀ and the refractive index n at the oscillation wavelength λ0 of the material to be used. Specifically, an odd multiple of λ₀/(4n) is preferable. For example, in a light emitting element having an oscillation wavelength λ₀ of 410 nm, in a case where the light reflecting layer includes SiO_{X}/NbO_{Y}, the thickness of approximately 40 nm to 70 nm can be exemplified. The number of laminated layers may be 2 or more, and preferably approximately 5 to 20. The thickness of the entire light reflecting layer can be, for example, approximately 0.6 μm to 1.7 μm. In addition, the light reflectance of the light reflecting layer is desirably 95% or more. The size and shape of the light reflecting layer are not particularly limited as long as the light reflecting layer covers the current injection region or the element region (these will be described later).

The light reflecting layer can be formed on the basis of a known method, and specifically, examples thereof include a PVD method such as a vacuum deposition method, a sputtering method, a reactive sputtering method, an ECR plasma sputtering method, a magnetron sputtering method, an ion beam assisted vapor deposition method, an ion plating method, or a laser ablation method; various CVD methods; an application method such as a spray method, a spin coating method, and a dipping method; a method of combining two or more of these methods; a method of, for example, entirely or partially combining these methods with any one or more of pretreatments, irradiation of inert gas (Ar, He, Xe, and the like) or plasma, irradiation of oxygen gas, ozone gas, or plasma, oxidation treatment (heat treatment), and exposure treatment.

As described above, the current injection region is provided in order to regulate the current injection into the active layer. The shape of the boundary between the current injection region and the current confinement region (current non-injection region) and the planar shape of the opening portion provided in the element region or the current confinement region are as described above. Here, the “element region” refers to a region into which a confined current is injected, a region in which light is confined due to a refractive index difference or the like, a region where laser oscillation occurs in a region sandwiched between the first light reflecting layer and the second light reflecting layer, or a region actually contributing to laser oscillation in a region sandwiched between the first light reflecting layer and the second light reflecting layer.

A side surface or an exposed surface of the laminated structure may be covered with a covering layer (insulating film). The coating layer (insulating film) can be formed on the basis of a known method. The refractive index of the material constituting the covering layer (insulating film) is preferably smaller than the refractive index of the material constituting the laminated structure. Examples of the material constituting the coating layer (insulating film) can include SiO_{X}-based materials including SiO₂, SiN_{X}-based materials, SiO_{Y}N_{z}-based materials, TaO_{X}, ZrO_{X}, AlN_{X}, AlO_{X}, and GaO_{X}, or organic materials such as polyimide-based resins. Examples of a method for forming the covering layer (insulating film) include a PVD method such as a vacuum deposition method or a sputtering method, and a CVD method, and the covering layer can also be formed on the basis of a coating method.

### Example 1

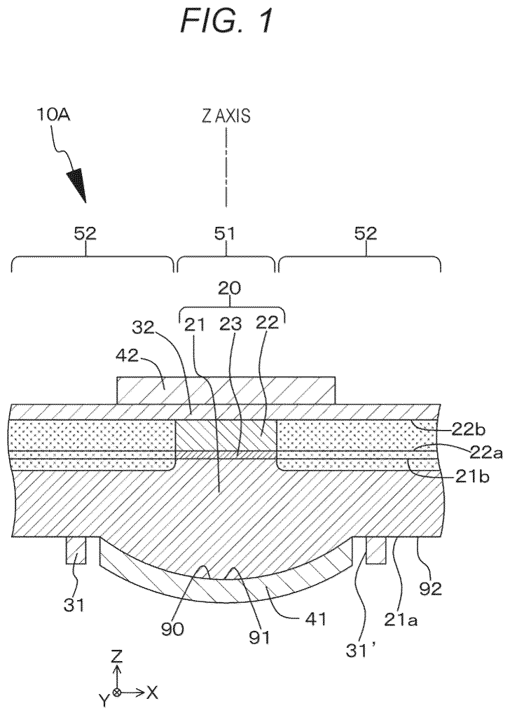

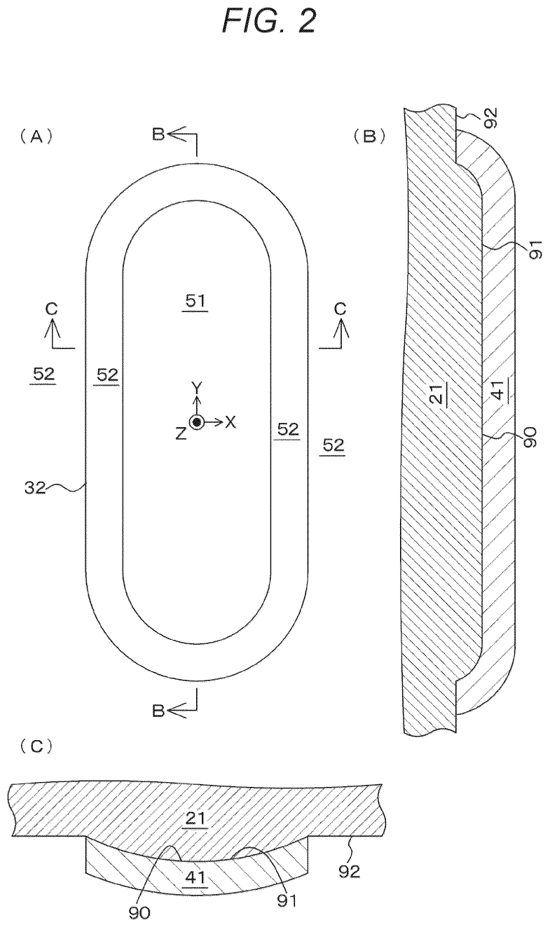

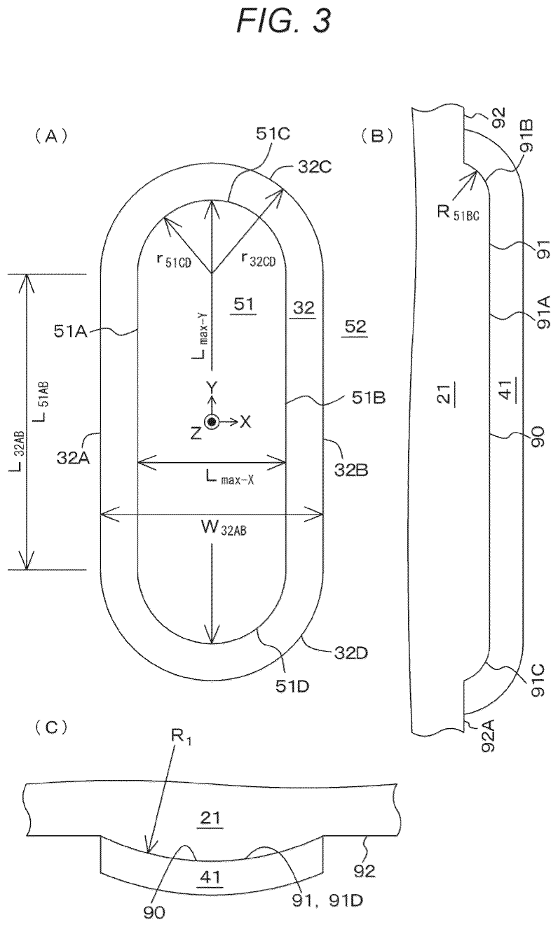

Example 1 relates to the light emitting element according to the first aspect of the present disclosure. The light emitting element of Example includes a surface light emitting laser element (vertical-cavity surface-emitting laser (VCSEL)) that emits laser light. FIG. 1 illustrates a schematic partial end view of the light emitting element of Example 1, (A) of FIG. 2 schematically illustrates an arrangement state of the current injection region, the current confinement region, and the second electrode constituting the light emitting element of Example 1, (B) and (C) of FIG. 2 illustrate schematic partial end views of the light emitting element of Example 1 along arrows B-B and arrows C-C in (A) of FIG. 2, and (A), (B), and (C) of FIG. 3 illustrate views which are substantially the same as (A), (B), and (C) of FIG. 2, but in which various parameters are written.

Note that descriptions of various symbols (refer to FIG. 3) used in the following description are summarized in Table 1 below. Reference numerals will be described later.

### <Table 1>

### [Light Emitting Element]

λ₀: Oscillation wavelength
L_{OR} Resonator length
θ_{Y} Emission angle of light in YZ virtual plane
θ_{X}: Emission angle of light in XZ virtual plane
   [Second electrode 32]
L_{32AB} Length of second electrode 32 in YZ virtual plane
W_{32AB} Length of second electrode 32 in XZ virtual plane
r_{32CD} Radius of semicircular part of second electrode 32 in XY virtual plane

### [Current Injection Region 51]

L_{max-Y}: Width of current injection region 51 along Y direction (length of current injection region 51 in YZ virtual plane)
L_{min-X}: Width of current injection region 51 along X direction (length of current injection region 51 in XZ virtual plane)
L_{51AB}: Length of two parallel line segments 51A and 51B constituting oval shape
r_{51CD}: Radius of semicircles 51C and 51D connecting one end portion and the other end of two line segments 51A and 51B

### [First Part 91 of Base Surface 90]

R₁: Radius of curvature of center portion 91_{c} of shape drawn by convex part when first part 91 of base surface 90 is cut along XZ virtual plane
R_{91BC}: Radius of curvature of end portion of first part 91 of base surface 90 when cut along YZ virtual plane
R₂: Radius of curvature of center portion 92_{c} of second part 92 of base surface 90 when cut along XZ virtual plane

### [Light Emitting Element Unit]

P_{X} Array pitch of plurality of light emitting elements
θ_{Y}′: Emission angle of light in YZ virtual plane
θ_{X}′:Emission angle of light in XZ virtual plane

A light emitting element 10A according to Example 1 or a light emitting element according to Examples 2 to 12 which will be described later includes: a laminated structure 20 in which a first compound semiconductor layer 21 having a first surface 21a and a second surface 21b opposing the first surface 21a, an active layer (light emitting layer) 23 facing the second surface 21b of the first compound semiconductor layer 21, and a second compound semiconductor layer 22 having a first surface 22a facing the active layer 23 and a second surface 22b opposing the first surface 22a are laminated; a first light reflecting layer 41 formed on the first surface side of the first compound semiconductor layer 21; a second light reflecting layer 42 formed on the second surface side of the second compound semiconductor layer 22; a first electrode 31 electrically connected to the first compound semiconductor layer 21; and a second electrode 32 electrically connected to the second compound semiconductor layer 22, and a current confinement region 52 that controls an inflow of a current to the active layer 23 is provided.

Then, in the light emitting element 10A of Example 1, when an axis in the thickness direction of the laminated structure 20 passing through the center of the current injection region 51 surrounded by the current confinement region 52 is defined as a Z axis, a direction orthogonal to the Z axis is defined as an X direction, and a direction orthogonal to the X direction and the Z axis is defined as a Y direction, the current injection region 51 has an elongated planar shape in which the longitudinal direction extends in the Y direction.

Here, in the light emitting element 10A according to Example 1, when a width of the current injection region 51 along the Y direction is L_{max-Y} and a width along the X direction is L_{min-X},

L_{max-Y}/L_{min-X}≥3
is satisfied, and
preferably,

L_{max-Y}/L_{min-X}≥20
is satisfied.

Further, in light emitting element 10A according to Example 1, the first light reflecting layer 41 has a convex shape toward a direction away from the active layer 23, and the second light reflecting layer 42 has a flat shape. In addition, in this case, the resonator length L_{OR} along the Z axis is not limited, and examples thereof include 1×10⁻⁵ m (10 μm)≤L_{OR}≤5×10⁻⁵ m (50 μm).

Furthermore, in the light emitting element 10A according to Example 1, the planar shapes of the first light reflecting layer 41 and the second electrode 32 are shapes (approximate shape) approximating the planar shape of the current injection region 51. In addition, the planar shape of the current injection region 51 is an oval shape. Note that the length L_{51AB} of the two parallel line segments 51A and 51B constituting the oval shape and the radius r_{51CD} of the semicircles 51C and 51D connecting one end portion and the other end of the two line segments 51A and 51B will be described later. Further, a length (length of line segments 32A and 32B of the second electrode 32 when the second electrode 32 is cut along the YZ virtual plane) L_{32AB} of the second electrode 32 in the YZ virtual plane, a length (length of the second electrode 32 when the second electrode 32 is cut along the XZ virtual plane) W_{32AB} of the second electrode 32 in the XZ virtual plane, and a radius r_{32CD}of the semicircular part of the second electrode 32 in the XY virtual plane will also be described later. The orthographic projection image of the current injection region 51 is included in the orthographic projection image of the second electrode 32. In addition, the orthographic projection image of the second electrode 32 is included in the orthographic projection image of the current confinement region 52.

Here, the first surface 21a of the first compound semiconductor layer 21 constitutes the base surface 90. With reference to the second surface 21b of the first compound semiconductor layer 21, the first part 91 of the base surface 90 on which the first light reflecting layer 41 is formed has an upward convex shape. In other words, the base surface 90 has a convex shape toward a direction away from the active layer 23. The second part 92, which is a part outside the first part 91 of the base surface 90, is flat and surrounds the first part 91 in Example 1. The first light reflecting layer 41 is formed on the first part 91 of the base surface 90 and is not formed on the second part 92 of the base surface 90.

The shape (figure) when the first part 91 of the base surface 90 is cut along the YZ virtual plane is a line segment 91A and parts 91B and 91C of a circle extending from one end and the other end of the line segment 91A (refer to (B) of FIG. 3). A line segment 92A and the line segment 91A when the second part 92 of the base surface 90 is cut along the YZ virtual plane are parallel. Further, a shape 91D drawn by the convex part when the first part 91 of the base surface 90 is cut along the XZ virtual plane is, for example, a part of a circle (refer to (C) of FIG. 3). The radius of curvature R_{91BC} of the end portions 91B and 91C of the first part 91 of the base surface 90 when cut along the YZ virtual plane will be described later.

In addition, as illustrated in (C) of FIG. 3, it is desirable that a radius of curvature R₁ of the center portion 91_{c} of the shape 91D (a curve drawn by the first part 91) drawn by the convex part when the first part 91 of the base surface 90 is cut along the XZ virtual plane satisfy 1.5×10⁻⁵ m (15 μm)≤R₁≤1×10⁻³ m (1 mm), and preferably, 3×10⁻⁵ m (30 μm)≤R₁≤1.5×10⁻⁴ m (150 μm).

The laminated structure 20 can include at least one type of material selected from the group consisting of a GaN-based compound semiconductor, an InP-based compound semiconductor, and a GaAs-based compound semiconductor.

Hereinafter, an example of a configuration of the light emitting element 10A of Example 1 will be described.

The first compound semiconductor layer 21 includes, for example, an n-GaN layer doped with Si of approximately 2×1016 cm⁻³, the active layer 23 includes a five-layered multiple quantum well structure in which an In_{0.04}Ga_{0.96}N layer (barrier layer) and an In_{0.16}Ga_{0.84}N layer (well layer) are laminated, and the second compound semiconductor layer 22 includes, for example, a p-GaN layer doped with magnesium of approximately 1×10¹⁹ cm⁻³. The plane orientation of the first compound semiconductor layer 21 is not limited to the {0001} plane, and may be, for example, a {20-21} plane which is a semipolar plane or the like. The first electrode 31 including Ti/Pt/Au is electrically connected to an external circuit or the like via a first pad electrode (not illustrated) including Ti/Pt/Au or V/Pt/Au, for example. On the other hand, the second electrode 32 is formed on the second compound semiconductor layer 22, and the second light reflecting layer 42 is formed on the second electrode 32. The second light reflecting layer 42 on the second electrode 32 has a flat shape. On the edge portion of the second electrode 32, for example, a second pad electrode (not illustrated) including Ti/Pt/Au, Ni/Pt/Au, Pd/Ti/Pt/Au, Ti/Pd/Au, Ti/Ni/Au, or Ti/Au for electric connection with an external circuit or the like may be formed or connected. The first light reflecting layer 41 and the second light reflecting layer 42 have a laminated structure of a Ta₂O₅ layer and a SiO₂ layer or a laminated structure of a SiN layer and a SiO₂ layer. The first light reflecting layer 41 and the second light reflecting layer 42 have a multi-layer structure as described above, but are represented by one layer for simplification of the drawing. The current injection region 51 is as described above. The planar shape of each of an opening portion 31′ provided in the first electrode 31, the first light reflecting layer 41, an opening portion 34A provided in an insulating layer (current confinement layer) 34, and the second light reflecting layer 42 is not limited, but is a shape (approximate shape) approximating the planar shape of the current injection region 51. The first compound semiconductor layer 21 has a first conductivity type (specifically, n-type), and the second compound semiconductor layer 22 has a second conductivity type (specifically, p-type) different from the first conductivity type.

In the laminated structure 20, the current injection region 51 and the current confinement region (current non-injection region) 52 surrounding the current injection region 51 are formed. Here, the current confinement region 52 is formed over a part of the first compound semiconductor layer 21 from the second compound semiconductor layer 22 in the thickness direction in the example illustrated in FIG. 1. However, the current confinement region 52 may be formed in a region of the second compound semiconductor layer 22 on the second electrode side in the thickness direction, may be formed in the entire second compound semiconductor layer 22, or may be formed in the second compound semiconductor layer 22 and the active layer 23. The current confinement region 52 can be formed on the basis of, for example, an ion implantation method of ion-implanting impurities (for example, at least one type of ion selected from the group consisting of boron, proton, phosphorus, arsenic, carbon, nitrogen, fluorine, oxygen, germanium, zinc, and silicon (that is, one type of ion or two or more types of ions)), and the current confinement region 52 including a region with reduced conductivity can be obtained.

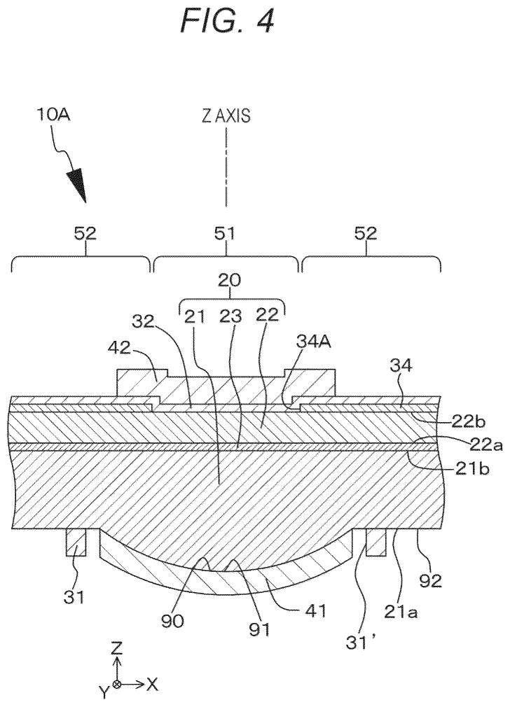

Alternatively, as illustrated in a schematic partial end view of Modification Example-1 of the light emitting element of Example 1 in FIG. 4, in order to obtain the current confinement region 52, an insulating layer (current confinement layer) 34 including an insulating material (for example, SiO_{X}, SiN_{X}, or AlO_{X}) may be formed between the second electrode 32 and the second compound semiconductor layer 22, and the insulating layer (current confinement layer) 34 is provided with an opening portion 34A for injecting a current into the second compound semiconductor layer 22. In other words, the second compound semiconductor layer 22 is partitioned into a first region 22A and a second region 22B surrounding the first region 22A, the second electrode 32 is provided on the first region 22A of the second compound semiconductor layer 22, and the second region 22B of the second compound semiconductor layer 22 opposes the second electrode 32 via the insulating layer 34.

Alternatively, in order to obtain the current confinement region, the second compound semiconductor layer 22 may be etched by the RIE method or the like to form a mesa structure, or at least a part of the laminated second compound semiconductor layer 22 may be partially oxidized from the lateral direction to form the current confinement region. Alternatively, the current confinement region may be formed by plasma irradiation (specifically, argon, oxygen, nitrogen, and the like) on the second surface of the second compound semiconductor layer, ashing treatment on the second surface of the second compound semiconductor layer, or reactive ion etching (RIE) treatment on the second surface of the second compound semiconductor layer. When the second surface of the second compound semiconductor layer is irradiated with plasma, the conductivity of the second compound semiconductor layer is deteriorated, and the current confinement region becomes a high resistance state.

Alternatively, these may be appropriately combined. However, the second electrode 32 needs to be electrically connected to a part (current injection region 51) of the second compound semiconductor layer 22 through which a current flows due to current confinement.

The second electrode 32 is connected to an external circuit or the like via the second pad electrode (not illustrated). The first electrode 31 is also connected to an external circuit or the like via the first pad electrode (not illustrated). The light may be emitted to the outside via the first light reflecting layer 41, or the light may be emitted to the outside via the second light reflecting layer 42.

Specifications of the laminated structure and the like of the light emitting element 10A of Example 1 are shown in the following Tables 2 and 3. Note that, in the light emitting element of Example 1 of which the specification is shown in Table 2, the second pad electrode is provided at a position that does not interfere with emission of light from the light emitting element, and has a structure capable of both emission of light via the first light reflecting layer 41 and emission of light via the second light reflecting layer 42. On the other hand, in the light emitting element of Example 1 of which the specification is shown in Table 3, the second pad electrode is formed so as to cover the second light reflecting layer 42 and the second electrode 32, and has a structure in which light is emitted via the first light reflecting layer 41. By providing such a second pad electrode, the light generated in the active layer 23 is reflected toward the first light reflecting layer 41, and the light emission efficiency can be improved.

TABLE 2

Second pad electrode Ti/Pt/Au
Second light reflecting layer 42 SiO₂/Ta₂O₅ (11.5 pairs)
Second electrode 32 ITO (thickness: 30 nm)
Second compound semiconductor layer 22 p-GaN
(thickness: 110 nm)
Active layer 23 Multiple quantum well structure (total
thickness: 15 nm)
Well layer InGaN
Barrier layer GaN
First compound semiconductor layer 21 n-GaN (Si-doped:
1 × 10¹⁸ cm⁻³)
First light reflecting layer 41 SiO₂/SIN (14 pairs)
First pad electrode V/Pt/Au
λ₀ 445 nm
L_{OR} 25 μm
θ_{Y} 1 degree or less
θ_{X} 9 degrees
L_{32AB} 46 μm
W_{32AB} 30 μm
r_{32CD} 15 μm
L_{max-Y} 50 μm
L_{min-X} 4 μm
L_{51AB} 46 μm
r_{51CD} 2 μm
R₁ 35 μm
R_{91BC} 35 μm

TABLE 3

Second pad electrode Ni/Pt/Au
Second light reflecting layer 42 SiO₂/Ta₂O₅ (14 pairs)
Second electrode 32 ITO (thickness: 40 nm)
Second compound semiconductor layer 22 p-GaN
(thickness: 100 nm)
Active layer 23 Multiple quantum well structure (total
thickness: 20 nm)
Well layer InGaN
Barrier layer GaN
First compound semiconductor layer 21 n-GaN (Ge-doped:
5 × 10¹⁸ cm⁻³)
First light reflecting layer 41 SiO₂/SiN (8 pairs)
First pad electrode V/Pt/Au
λ₀ 455 nm
L_{OR} 20 μm
θ_{Y} 1 degree or less
θ_{X} 7 degrees
L_{32AB} 46 μm
W_{32AB} 40 μm
r_{32CD} 20 μm
L_{max-Y} 50 μm
L_{min-X} 4 μm
L_{51AB} 46 μm
r_{51CD} 2 μm
R₁ 25 μm
R_{91BC} 60 μm

It can be found from Tables 2 and 3 that the light emission angle θ_{Y} in the YZ virtual plane can be set to 2 degrees or less.

Hereinafter, an outline of the method for manufacturing the light emitting element 10A of Example 1 will be described.

First, after the laminated structure 20 is formed, the second light reflecting layer 42 is formed on the second surface side of the second compound semiconductor layer 22.

### [Step—100]

Specifically, on a second surface 11b of the compound semiconductor substrate 11 having a thickness of approximately 0.4 mm, the laminated structure 20 is formed which includes a GaN-based compound semiconductor and in which the first compound semiconductor layer 21 having the first surface 21a and the second surface 21b opposing the first surface 21a, the active layer (light emitting layer) 23 facing the second surface 21b of the first compound semiconductor layer 21, and the second compound semiconductor layer 22 having the first surface 22a facing the active layer 23 and the second surface 22b opposing the first surface 22a are laminated. More specifically, the laminated structure 20 can be obtained by sequentially forming the first compound semiconductor layer 21, the active layer 23, and the second compound semiconductor layer 22 on the second surface 11b of the compound semiconductor substrate 11 on the basis of an epitaxial growth method by a known MOCVD method (refer to FIG. 21A).

### [Step—110]

Next, the current confinement region 52 is formed in the laminated structure 20 on the basis of a known ion implantation method using boron ions (refer to FIG. 21B).

### [Step—120]

Thereafter, the second electrode 32 is formed on the second compound semiconductor layer 22 on the basis of a sputtering method.

### [Step—130]

Next, the second light reflecting layer 42 is formed on the second electrode 32. Specifically, the second light reflecting layer 42 is formed, from the top of the second electrode 32 to the top of the second pad electrode on the basis of a combination of a film forming method such as a sputtering method or a vacuum deposition method and a patterning method such as a wet etching method or a dry etching method. The second light reflecting layer 42 on the second electrode 32 has a flat shape. In this manner, the structure illustrated in FIG. 22 can be obtained.

### [Step—140]

Next, the second light reflecting layer 42 is fixed to a support substrate 49 via a bonding layer 48 (refer to FIG. 23). Specifically, the second light reflecting layer 42 is fixed to the support substrate 49 including a sapphire substrate using the bonding layer 48 including an adhesive.

### [Step—150]

Next, the compound semiconductor substrate 11 is thinned on the basis of a mechanical polishing method or a CMP method, and is further etched to remove the compound semiconductor substrate 11.

### [Step—160]

Thereafter, a sacrificing layer 81 is formed on the region where the first part 91 of the base surface 90 (specifically, the first surface 21a of the first compound semiconductor layer 21) on which the first light reflecting layer 41 is to be formed is to be formed, and then the surface of the sacrificing layer 81 is made convex. Specifically, a resist material layer is formed on the first surface 21a of the first compound semiconductor layer 21, the resist material layer is patterned to leave the resist material layer on a region where the first part 91 of the base surface 90 is to be formed (refer to FIG. 24A), and then the remaining resist material layer is subjected to heat treatment, whereby a sacrificing layer 81′ having a convex surface can be obtained (refer to FIG. 24B). Next, by etching back the sacrificing layer 81′ and further etching back from the base surface 90 toward the inside (that is, from the first surface 21a of the first compound semiconductor layer 21 to the inside of the first compound semiconductor layer 21), a convex portion can be formed in the first part 91 of the base surface 90 with reference to the second surface 21b of the first compound semiconductor layer 21 (refer to FIG. 24C). The first part 91 of the base surface 90 and the second part 92 corresponding to the region between the first part 91 and the second part 92 are flat. Etching back can be performed on the basis of a dry etching method such as a RIE method, or can be performed on the basis of a wet etching method using hydrochloric acid, nitric acid, hydrofluoric acid, phosphoric acid, a mixture thereof, or the like. Note that, in FIGS. 24A, 24B, and 24C, and FIGS. 25A, 25B, 25C, 26A, 26B, 26C, 27A, and 27B to be described later, illustration of the active layer, the second compound semiconductor layer, the second light reflecting layer, and the like is omitted.

### [Step—170]

Next, the first light reflecting layer 41 is formed on the convex portion 91 of the base surface 90. Specifically, the first light reflecting layer 41 is formed on the entire surface of the base surface 90 on the basis of a film forming method such as a sputtering method or a vacuum deposition method, and then the first light reflecting layer 41 is patterned, whereby the first light reflecting layer 41 can be obtained on the convex portion 91 of the base surface 90. Thereafter, the first electrode 31 is formed on a region of the base surface 90 where the first light reflecting layer 41 is not formed. As described above, the light emitting element 10A of Example 1 illustrated in FIG. 1 can be obtained. When the first electrode 31 protrudes from the first light reflecting layer 41, the first light reflecting layer 41 can be protected. Then, electric connection to an external electrode or circuit (circuit for driving the light emitting element) is only required to be achieved. Specifically, the first compound semiconductor layer 21 is only required to be connected to an external circuit or the like via the first electrode 31 and the first pad electrode (not illustrated), and the second compound semiconductor layer 22 may be connected to an external circuit or the like via the second electrode 32 and the second pad electrode. Next, the light emitting element 10A of Example 1 is completed by packaging or sealing.

Incidentally, three notable findings can be cited as the physical background of semiconductor lasers.

The first finding is the stimulated emission predicted by Einstein. This is a phenomenon in which a certain mode is enhanced when transitioning from a certain state to another state. Such a phenomenon occurs when the state of the transition source is inversely distributed and the state of the transition destination is a boson. In a case of a semiconductor laser, laser light having a specific mode is generated by transitioning (stimulated emission) the electron-hole in the inverted distribution state to light. At this time, in order to guide the electron-hole to the inverted distribution state, it is required to locally inject a current, that is, to confine electrons and light in a narrow region.

The second finding is consideration of the uncertainty of the state predicted by Schrödinger. It has been predicted that a quantum including light can take a plurality of states at the same time, and the states are determined by observation. This is famous as a thought experiment called “Schrödinger's cat”. In a case where a certain quantum takes a plurality of states at the same time as described above, these states are often expressed as “overlapping”, “coupled”, “phase matched (coherent)”, and the like.

The third finding is the uncertainty principle proposed by Heisenberg. This is on the basis of the assumption that the degrees of uncertainty of the respective physical quantities of the quantum have a causal relationship with each other. In particular, it has been predicted that the uncertainty of position and momentum are inversely proportional to each other. This is nothing less than the relationship between the minimum width of the light beam (or uncertainty of position of the light beam in a plane perpendicular to the traveling direction) and the emission angle (radiation angle) in the semiconductor laser. The fact that the emission angle is suppressed by enlarging the minimum width of the light beam and light having high straightness is obtained is also known as a diffraction phenomenon even before quantum mechanics.

According to the uncertainty principle of Heisenberg, widening the minimum width of the light beam (or the uncertainty of position in the plane perpendicular to the traveling direction), that is, widening the width of the light beam, is effective for reducing the emission angle. In order to achieve this goal, it is important to enlarge the light-confinement region. For example, in a case of a ridge waveguide type end surface laser, which is widely used today, an approach of enlarging a ridge width can be considered, and in a case of an oxidation constriction type surface light emitting laser element, an approach of enlarging a non-oxidation constriction region, that is, enlarging a current injection region can be considered. However, in a case of enlarging the current injection region, the laser light is not widely distributed in the surface light emitting laser element, and a plurality of modes may be individually generated with locally non-coaxial spatial arrangement in various regions. In this case, since the spatial uncertainty is reduced, the emission angle corresponding to the designed size of the light confinement region cannot be obtained, and rather increases. For example, in a case of a surface light emitting laser element, there is a concern that a separate mode becomes dominant between a certain region and another region of the surface light emitting laser element due to a phenomenon such as undulation of a light reflecting layer, a defect present in a compound semiconductor crystal, and nonuniformity of conductivity. In such a case, since the quantum state of the laser light does not spread as much as the size of the light confinement region, the emission angle of the light beam becomes larger than that in a case where the light spreads over the entire light confinement region. In other words, simply enlarging the optical confinement region is not sufficient to realize wide light confinement.

Further, in the semiconductor laser element, the region in which the light is confined and the region in which the current is confined overlap each other. Therefore, in many cases, it is also necessary to enlarge the current injection region. However, in a case where a current is injected into a large region, a larger current is required to obtain an inverted distribution, and thus problems such as an increase in power consumption, an increase in heat generation, and deterioration in reliability are associated.

In the light emitting element of Example 1, in order to realize a wide light confinement region, not only the optical confinement region needs to be enlarged, but also the current injection region needs to be enlarged, such that the current injection region has a shape specificity such as an elongated planar shape of which the longitudinal direction extends in the Y direction. As a result, the width along the Y direction of the light beam emitted from the light emitting element is enlarged, and the emission angle of the light beam along the Y direction can be reduced. In other words, the emission angle θ_{Y} of the light in the YZ virtual plane can be made smaller than the emission angle θ_{X} of the light in the XZ virtual plane. Thus, it is possible to obtain a light emitting element having a light beam having high straightness in the YZ virtual plane of the light beam, which is not included in the light emitting element of the related art.

In addition, when the shape of the end region of the light field confinement region in the Y direction is a circular shape in a planar manner (a spherical shape in a stereoscopic manner), light that tries to escape from the end region to the outside of the light emitting element can be confined inside the light emitting element, loss of light is reduced, and light emission efficiency of the light emitting element can be improved.

In addition, the cross-sectional shape of the emitted light in the light emitting element of Example 1 (the shape of the emitted light when it is assumed that the emitted light is cut along a virtual plane perpendicular to the traveling direction of the emitted light) is a “rod shape” or an “I shape” extending in the Y direction. Then, for example, in a case where it is desired to irradiate a wider range in the X direction, it is possible to easily irradiate a distant place while satisfying such a requirement without using an external optical system such as a lens or by using a simple external optical system, and it is possible to obtain a light beam with less radiation in the Y direction and high straightness and a light beam with a high quality Gaussian profile in the X direction. In addition, as compared with the light emitting element of the related art, a larger volume of the active layer (light emitting layer) can contribute to light emission, and thus an increase in output (for example, 100 milliwatts or more) of the light emitting element can be achieved. Moreover, since the distance from the second electrode to each region of the current injection region can be shortened, a current can uniformly flow through the active layer having a large area, and highly efficient light emitting element driving can be performed as compared with the light emitting element of the related art.

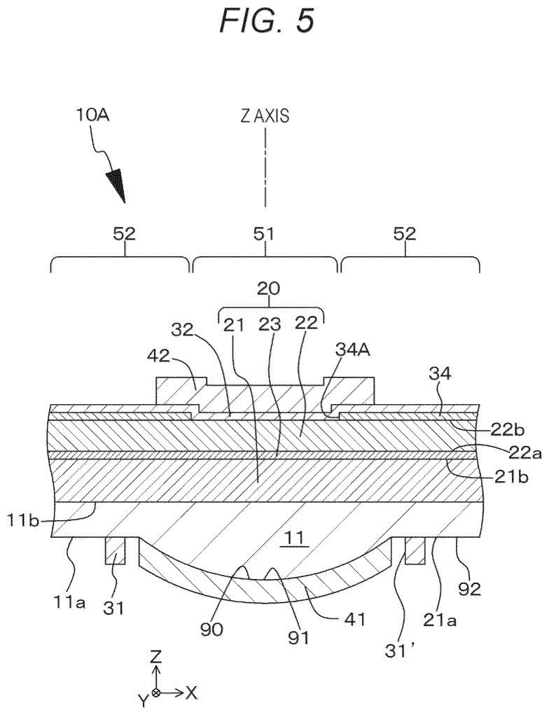

In Modification Example-2 of the light emitting element of Example 1 in which a schematic partial end view is illustrated in FIG. 5, the compound semiconductor substrate 11 is disposed (left) between the first surface 21a of the first compound semiconductor layer 21 and the first light reflecting layer 41, and the base surface 90 including the surface (first surface 11a) of the compound semiconductor substrate 11. Note that, in FIG. 5, the light emitting element based on the light emitting element of Modification Example-1 of Example 1 is illustrated, but the present disclosure is not limited thereto.

In Modification Example-2 of the light emitting element of Example 1, the compound semiconductor substrate 11 is thinned and mirror-finished in the similar step as [Step—150] of Example 1. The value of a surface roughness Ra of the first surface 11a of the compound semiconductor substrate 11 is preferably 10 nm or less. The surface roughness Ra is specified in JIS B-610:2001, and can be specifically measured on the basis of observation based on AFM or cross-sectional TEM. Thereafter, a sacrificing layer in [Step—160] of Example 1 is formed on the exposed surface (first surface 11a) of the compound semiconductor substrate 11, and hereinafter, the similar step as the step after [Step—160] of Example 1 is executed, and the base surface 90 including the first part 91 and the second part 92 may be provided on the compound semiconductor substrate 11 instead of the first compound semiconductor layer 21 in Example 1 to complete the light emitting element. In addition, the first electrode 31 is only required to be formed on the compound semiconductor substrate 11.

Alternatively, the first light reflecting layer 41 may be formed on a sapphire substrate as a light emitting element manufacturing substrate. In this case, the first electrode 31 is only required to be connected to the first compound semiconductor layer 21 in a region (not illustrated).

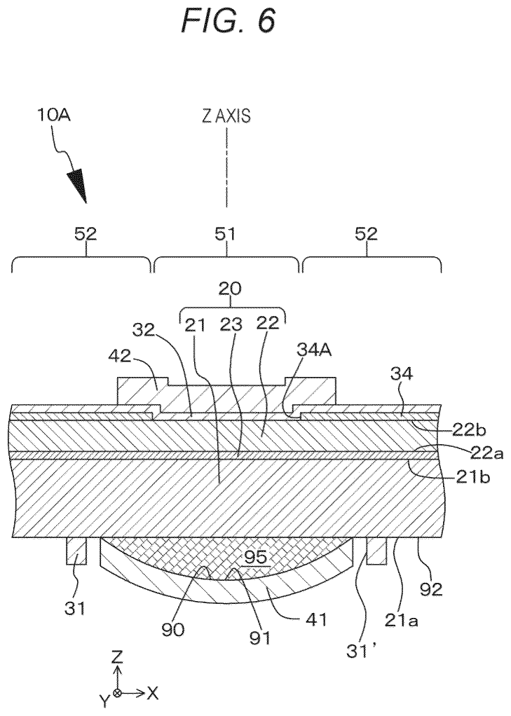

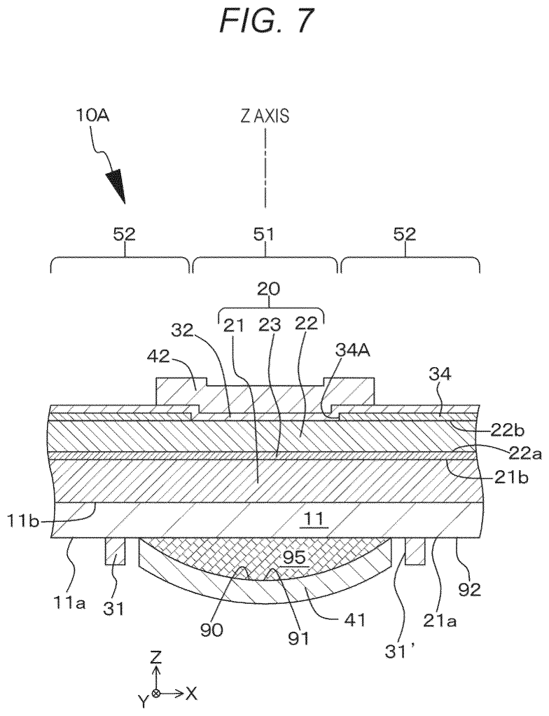

Alternatively, in Modification Example-3 of the light emitting element of Example 1 in which a schematic partial end view is shown in FIG. 6, a base material 95 is disposed between the first surface 21a of the first compound semiconductor layer 21 and the first light reflecting layer 41, and the base surface 90 includes the surface of the base material 95. Alternatively, in Modification Example-4 of the light emitting element of Example 1 in which a schematic partial end view is shown in FIG. 7, the compound semiconductor substrate 11 and the base material 95 are disposed between the first surface 21a of the first compound semiconductor layer 21 and the first light reflecting layer 41, and the base surface 90 includes the surface of the base material 95. Examples of the material constituting the base material 95 include transparent dielectric materials such as TiO₂, Ta₂O₅, and SiO₂, silicone-based resins, epoxy-based resins, and the like. Note that, in FIGS. 6 and 7, the light emitting element based on the light emitting element of Modification Example-1 of Example 1 is illustrated, but the present disclosure is not limited thereto.

In Modification Example-3 of the light emitting element of Example 1 shown in FIG. 6, in a step similar to [Step—150] of Example 1, the compound semiconductor substrate 11 is removed, and the base material 95 having the base surface 90 is formed on the first surface 21a of the first compound semiconductor layer 21. Specifically, for example, a TiO₂ layer or a Ta₂O₅ layer is formed on the first surface 21a of the first compound semiconductor layer 21, a patterned resist layer is then formed on the TiO₂ layer or the Ta₂O₅ layer on which the first part 91 is to be formed, and the resist layer is heated to reflow the resist layer, thereby obtaining a resist pattern. The resist pattern is provided with the same shape (or a similar shape) as the shape of the first part. Then, by etching back the resist pattern and the TiO₂ layer or the Ta₂O₅ layer, the base material 95 (including the TiO₂ layer or the Ta₂O₅ layer) in which the first part 91 and the second part 92 are provided on the first surface 21a of the first compound semiconductor layer 21 can be obtained. Next, the first light reflecting layer 41 is only required to be formed on a desired region of the base material 95 on the basis of a known method.

Alternatively, in Modification Example-4 of the light emitting element of Example 1 shown in FIG. 7, the base material 95 having the base surface 90 is formed on the exposed surface (first surface 11a) of the compound semiconductor substrate 11 after thinning the compound semiconductor substrate 11 and performing mirror finishing in a step similar to [Step—150] of Example 1. Specifically, for example, a TiO₂ layer or a Ta₂O₅ layer is formed on the exposed surface (first surface 11a) of the compound semiconductor substrate 11, a patterned resist layer is then formed on the TiO₂ layer or the Ta₂O₅ layer on which the first part 91 is to be formed, and the resist layer is heated to reflow the resist layer, thereby obtaining a resist pattern. The resist pattern is provided with the same shape (or a similar shape) as the shape of the first part. Then, by etching back the resist pattern and the TiO₂ layer or the Ta₂O₅ layer, the base material 95 (including the TiO₂ layer or the Ta₂O₅ layer) in which the first part 91 and the second part 92 are provided on the exposed surface (first surface 11a) of the compound semiconductor substrate 11 can be obtained. Next, the first light reflecting layer 41 is only required to be formed on a desired region of the base material 95 on the basis of a known method.

### Example 2

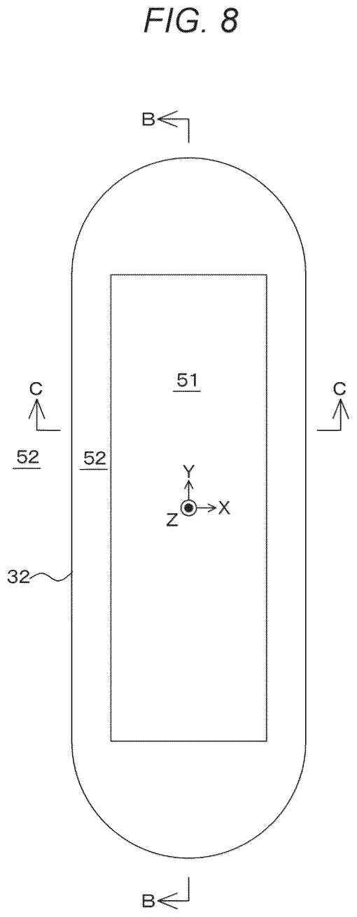

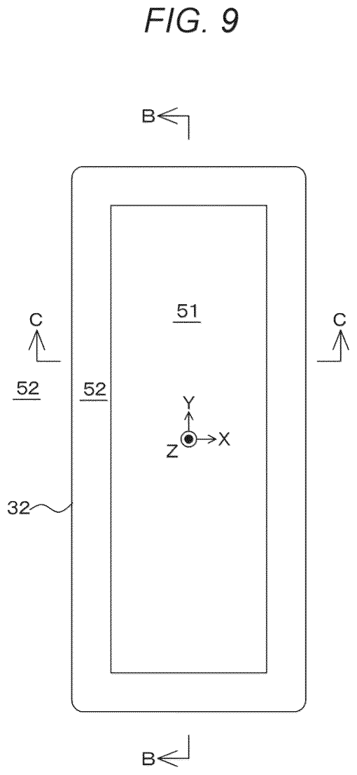

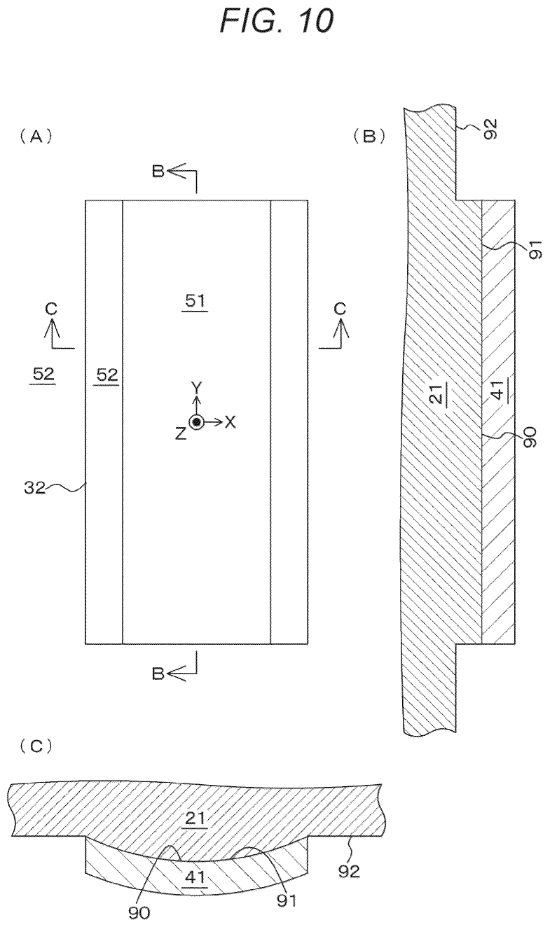

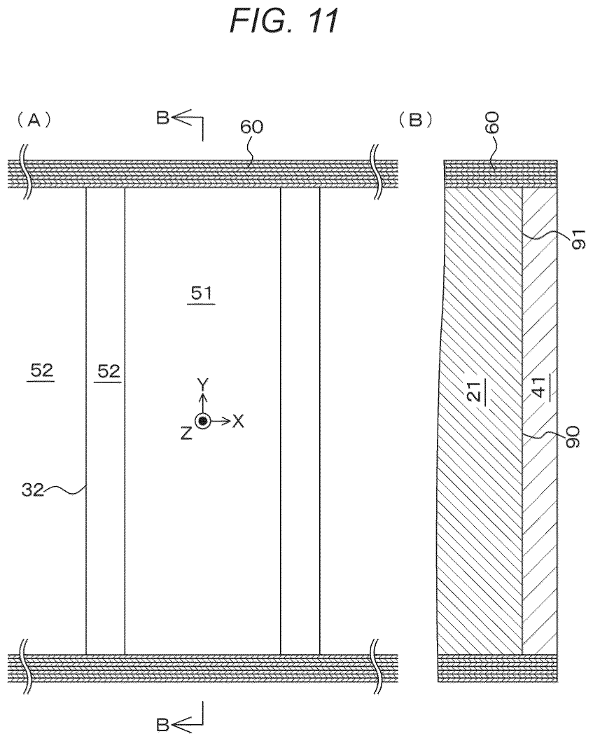

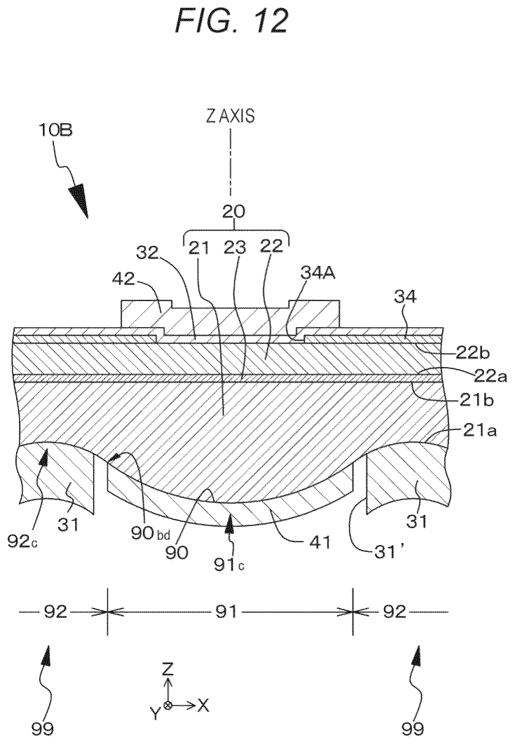

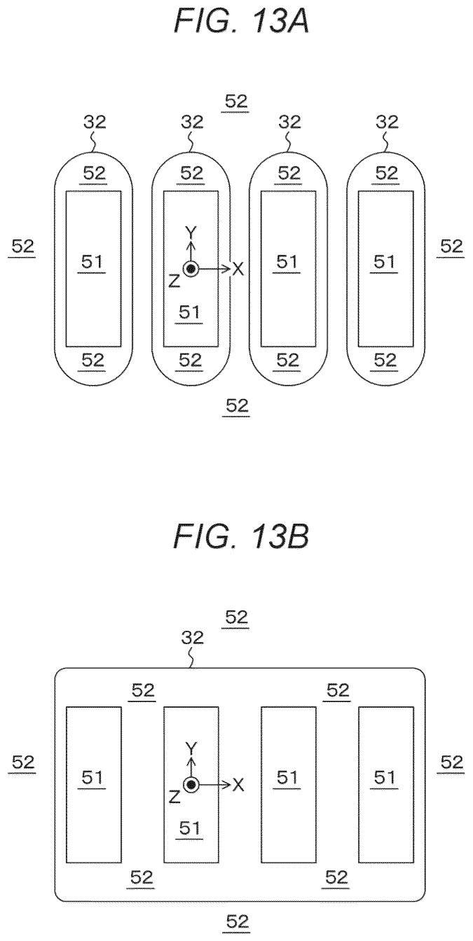

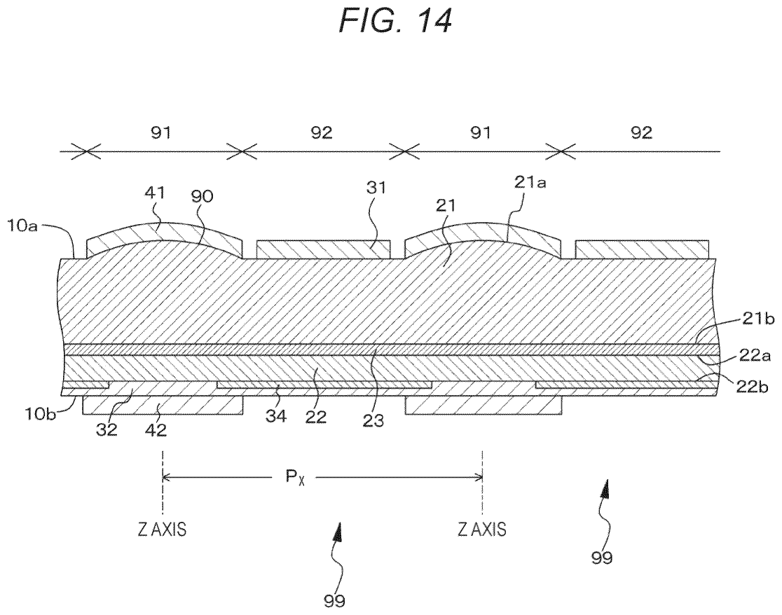

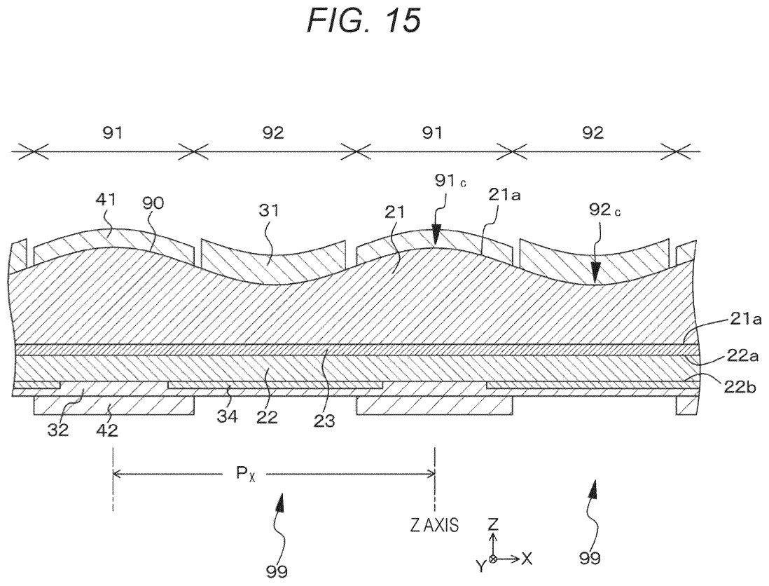

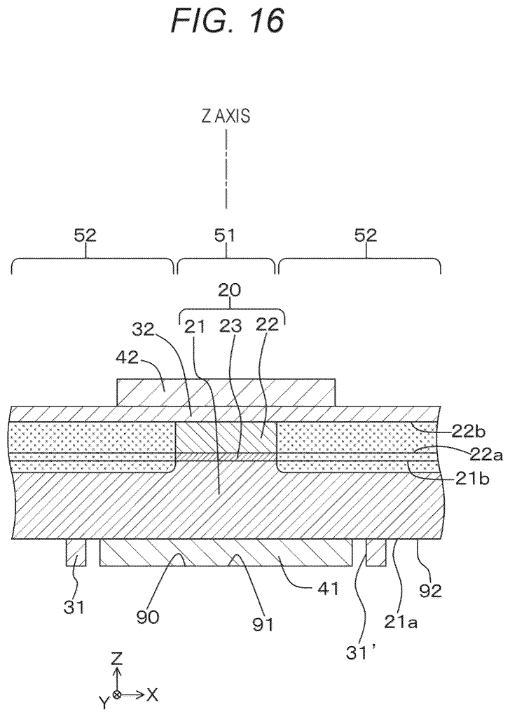

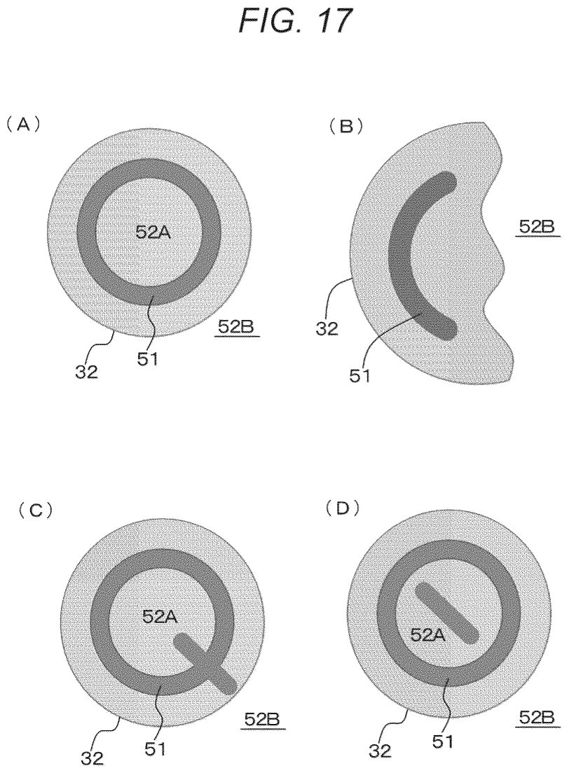

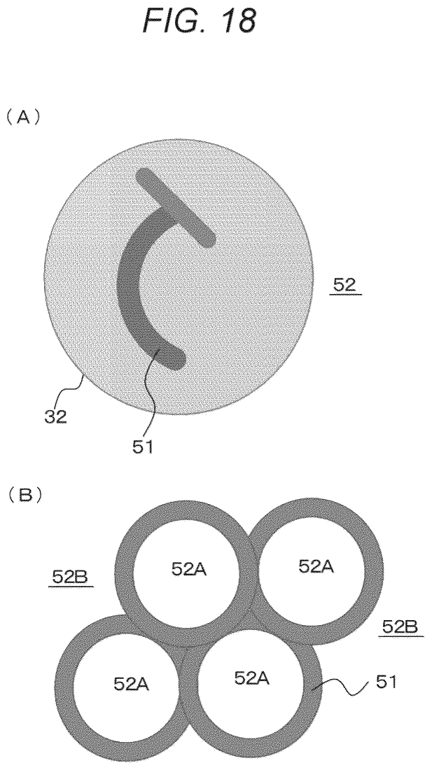

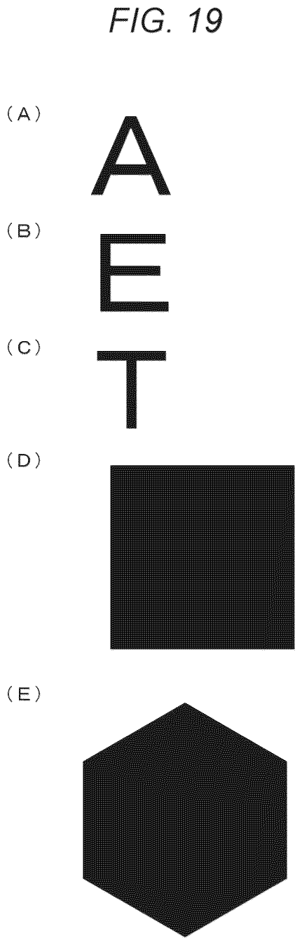

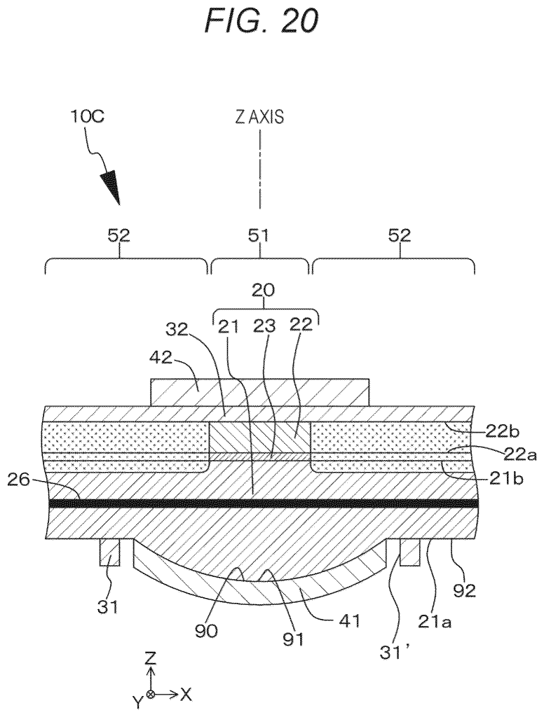

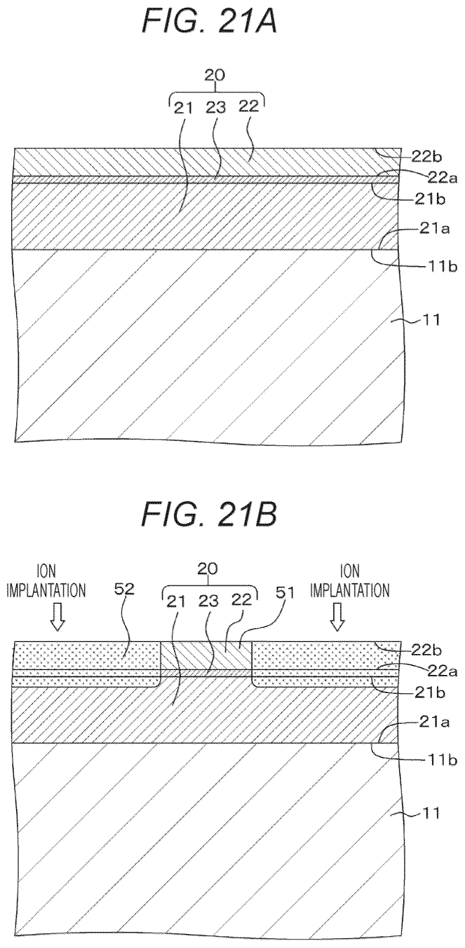

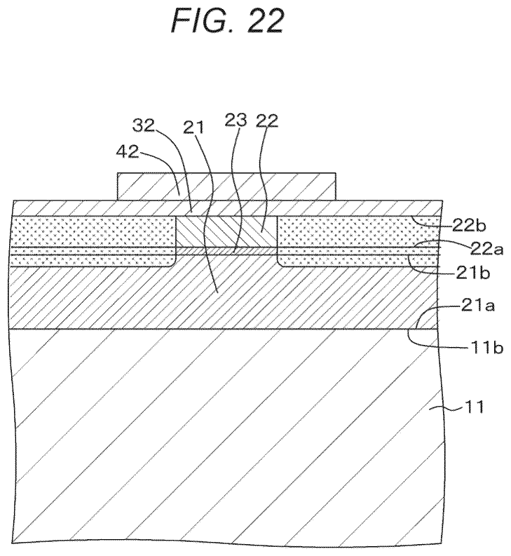

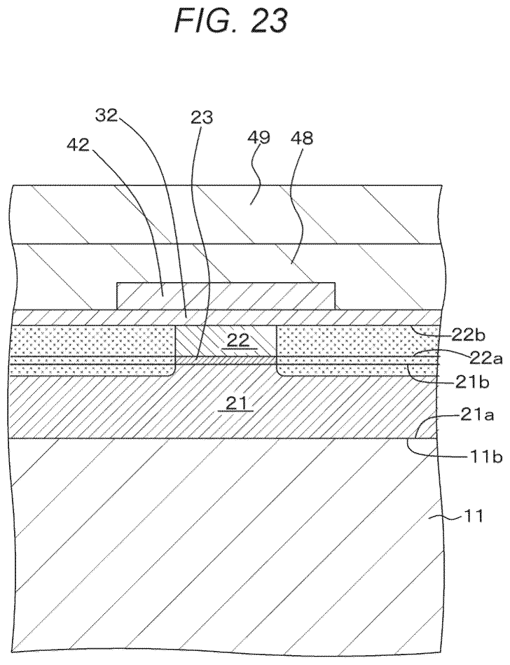

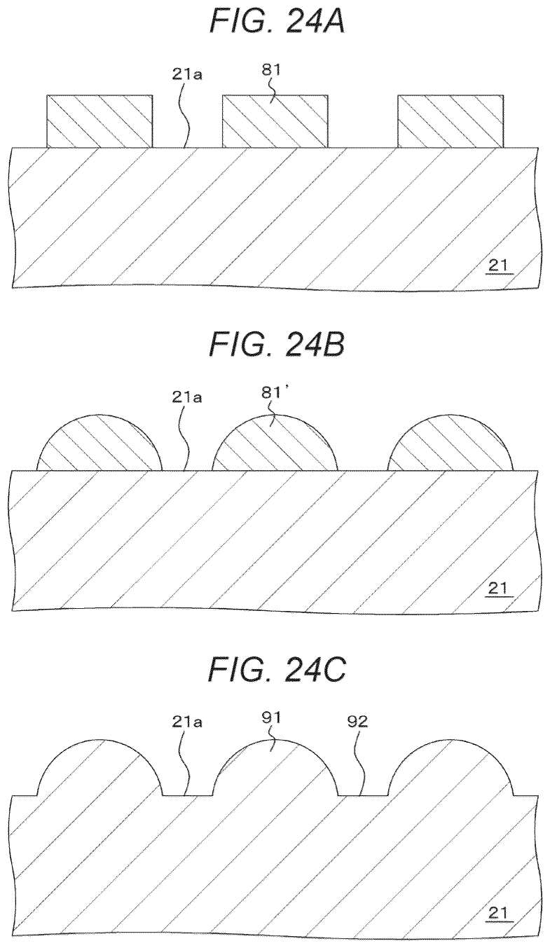

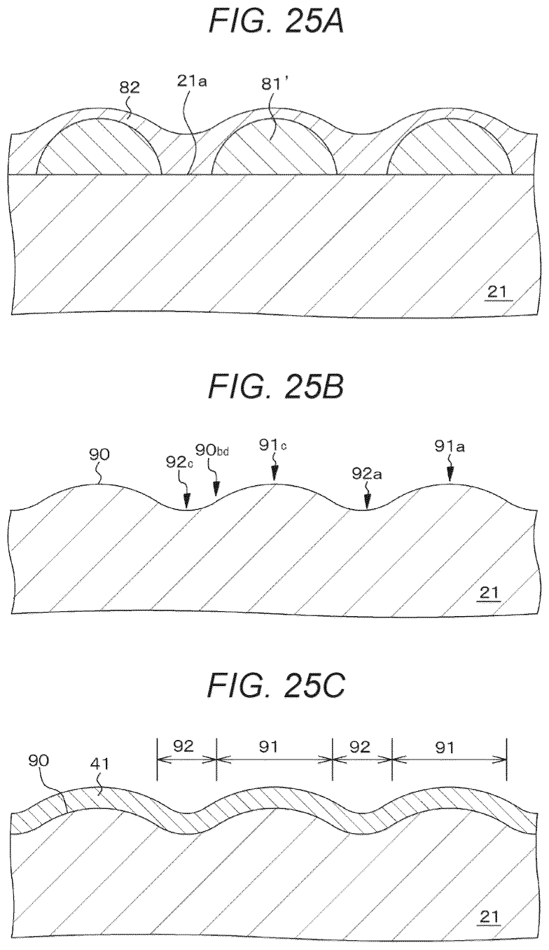

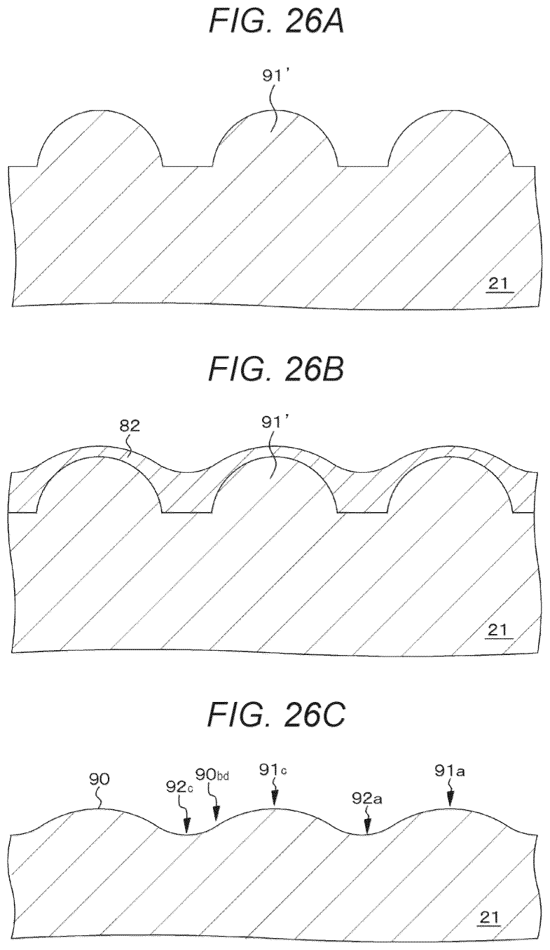

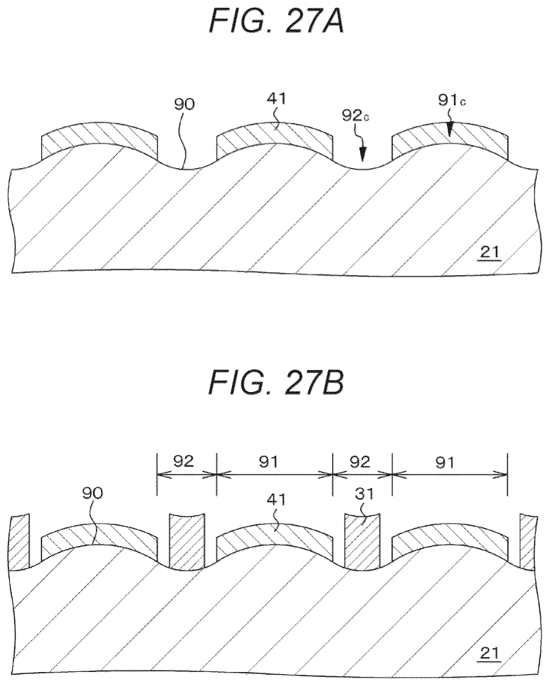

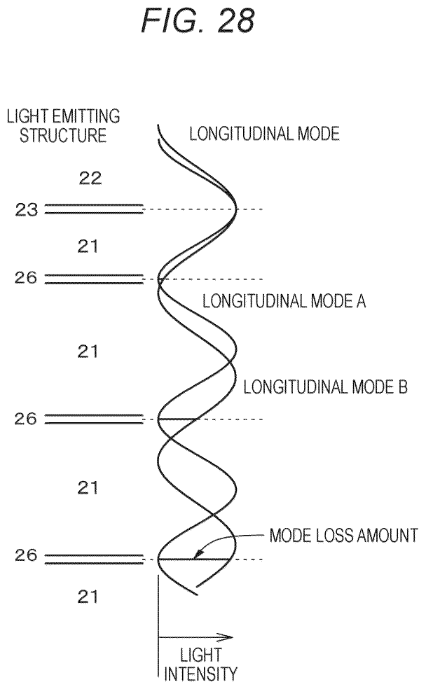

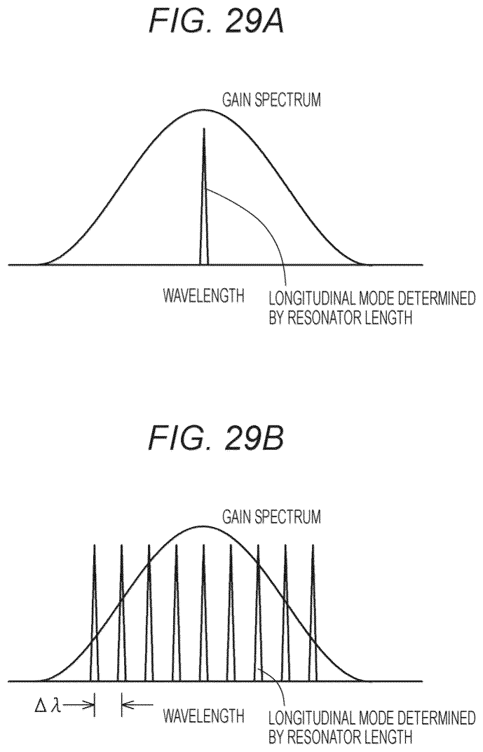

Example 2 is a modification of Example 1. FIGS. 8 and 9 schematically illustrate the arrangement state of the current injection region, the current confinement region, and the second electrode constituting the light emitting element of Example 2, and in the light emitting element of Example 2, the planar shape of the current injection region 51 is a rectangular shape. On the other hand, the planar shape of the second electrode 32 is an oval shape (FIG. 8) or a rectangular shape with rounded four corners (refer to FIG. 9). The current confinement region 52 surrounds the current injection region 51. Similarly to Example 1, the orthographic projection image of the current injection region 51 is included in the orthographic projection image of the second electrode 32. In addition, the orthographic projection image of the second electrode 32 is included in the orthographic projection image of the current confinement region 52.

Specifications of the laminated structure and the like of the light emitting element of Example 2 are shown in the following Table 4. In the light emitting element of which the specification is shown in Table 4, the second pad electrode is formed so as to cover the second light reflecting layer 42 and the second electrode 32, and has a structure in which light is emitted via the first light reflecting layer 41. The side parallel to the Y direction of the current injection region 51 may include a line segment or a curve. The schematic partial end views taken along arrows B-B in FIGS. 8 and 9 and the schematic partial end views taken along arrows C-C in FIGS. 8 and 9 are substantially the same as the schematic partial end views illustrated in (B) and (C) of FIG. 2.

TABLE 4

Second pad electrode Ti/Au
Second light reflecting layer 42 SiO₂/Ta₂O₅ (14 pairs)
Second electrode 32 ITO (thickness: 20 nm)
Second compound semiconductor layer 22 p-GaN
(thickness: 100 nm)
Active layer 23 Multiple quantum well structure (total
thickness: 25 nm)
Well layer InGaN (Si-doped: 2 × 10¹⁸ cm⁻³)
Barrier layer GaN
First compound semiconductor layer 21 n-GaN
First light reflecting layer 41 SiO₂/SiN (9 pairs)
First pad electrode V/Pt/Au
λ₀ 405 nm
L_{OR} 35 μm
θ_{Y} 1 degree or less
θ_{X} 15 degrees
L_{32AB} 500 μm
W_{32AB} 25 μm
r_{32CD} 25 μm
L_{max-Y} 25 μm
L_{min-X} 6 μm
L_{51AB} 25 μm
r_{51CD} —
R₁ 45 μm
R₁ 20 μm
R_{91BC} 20 μm

The light emitting element of Example 2 has a smaller value of L_{max-Y} and a larger value of L_{min-X} than those of the light emitting element of Example 1 shown in Table 2. Therefore, the value of θ_{Y} and the value of 8x are also larger than those of the light emitting element of Example 1 shown in Table 2. From this result, it was found that by appropriately designing the value of L_{max-Y} and the value of L_{min-X}, the emission angle of the light beam from the light emitting element can be set to a desired value, that is, the emission angle can be controlled. In addition, when the shape of the end region of the light field confinement region in the Y direction is a circular shape in a planar manner (a spherical shape in a stereoscopic manner), light that tries to escape from the end region to the outside of the light emitting element can be confined inside the light emitting element, loss of light is reduced, and light emission efficiency of the light emitting element can be improved. Moreover, since the planar shape of the current injection region is a rectangular shape, it is possible to prevent the current from excessively flowing into the end region in the Y direction of the current injection region, it is possible to suppress localization of the light emitting state in the end region, and as a result, it is possible to maintain the light emitting state in the entire element region in coherence. In addition, the manufacturing yield of the light emitting element can be improved.

Two of the light emitting elements of Example 2 were arranged in the Y direction such that the YZ virtual planes overlapped with each other. The distance between the second electrode 32 and the second electrode 32 in the two light emitting elements along the Y direction was set to 5 μm. As a result, the uncertainty of the position of the light in the Y direction can be increased as compared with the case of one light emitting element, and the value of θ₂ is 0.01 degrees or less. In addition, even when the total length of the current injection region 51 in the Y direction is the same as 50 μm, by adopting a structure in which two light emitting elements (refer to Example 2) are arranged rather than one light emitting element (refer to Example 1), the value of θ_{Y} becomes a smaller value.

(A) of FIG. 10 is a view schematically illustrating the arrangement state of the current injection region, the current confinement region, and the second electrode constituting Modification Example-1 of the light emitting element of Example 2, and (B) and (C) of FIG. 10 are schematic partial end views of Modification Example-1 of the light emitting element of Example 2 along arrows B-B and arrows C-C in (A) of FIG. 10. In this Modification Example-1, the planar shape of the current injection region 51 and the second electrode 32 is a rectangular shape. Then, the orthographic projection image of the side of the second electrode 32 parallel to the X direction and the orthographic projection image of the side of the current injection region 51 parallel to the X direction coincide with each other (refer to (A) and (B) of FIG. 10). Alternatively, the distance between the orthographic projection image of the side of the current injection region 51 parallel to the X direction and the orthographic projection image of the side of the second electrode 32 parallel to the X direction is within 5 μm. In other words, with reference to the orthographic projection image of the side of the current injection region 51 parallel to the X direction, the orthographic projection image of the side of the second electrode 32 parallel to the X direction may be positioned at a distance of 5 μm or less on the outer side in the Y direction, or may be positioned at a distance of 5 μm or less on the inner side. With such a configuration, it is possible to prevent the current from excessively flowing into the end region in the Y direction of the current injection region 51 having a rectangular planar shape, it is possible to suppress localization of the light emitting state in the end region, and as a result, it is possible to maintain the light emitting state in the entire element region in coherence. In addition, the manufacturing yield of the light emitting element can also be improved. Specifications of the laminated structure and the like of Modification Example-1 of the light emitting element of Example 2 are shown in the following Table 5. A side surface including a side parallel to the X direction of the current injection region 51 may be in contact with the current confinement region 52, or an end surface including a side parallel to the X direction of the current injection region 51 may include a cut surface of the laminated structure 20. In other words, the end surface including the side parallel to the X direction of the current injection region 51 may be in contact with the atmosphere, for example. Furthermore, the side parallel to the Y direction of the current injection region 51 may include a line segment or a curve.

TABLE 5

Second pad electrode Ti/Pt/Au
Second light reflecting layer 42 SiO₂/Ta₂O₅ (11.5 pairs)
Second electrode 32 ITO (thickness: 30 nm)
Second compound semiconductor layer 22 p-GaN
(thickness: 140 nm)
Active layer 23 Multiple quantum well structure (total
thickness: 15 nm)
Well layer InGaN (Si-doped: 1 × 10¹⁸ cm⁻³)
Barrier layer GaN
First compound semiconductor layer 21 n-GaN
First light reflecting layer 41 SiO₂/SiN (14 pairs)
First pad electrode V/Pt/Au
λ₀ 515 nm
L_{OR} 15 μm
θ_{Y} 2 degrees or less
θ_{X} 15 degrees
L_{32AB} 50 μm
W_{32AB} 25 μm
r_{32CD} —
L_{max-Y} 50 μm
L_{min-X} 4 μm
L_{51AB} 50 μm
r_{51CD} —
R₁ 25 μm

(A) of FIG. 11 schematically illustrates the arrangement state of the current injection region, the current confinement region, and the second electrode constituting Modification Example-2 of the light emitting element of Example 2, and (B) of FIG. 11 illustrates a schematic partial end view along arrows B-B. Modification Example-2 is a modification of Modification Example-1, and the end surface including the side parallel to the X direction of the current injection region 51 is in contact with the layer (laminated film) 60 in which the first dielectric layer and the second dielectric layer are alternately arranged in the Y direction. The outer surface of the laminated film 60 may be in contact with the current confinement region 52, or may be in contact with the atmosphere, for example. In an aspect in which the outer surface of the laminated film 60 is in contact with the current confinement region 52, the laminated film 60 has, for example, a similar configuration and structure although the lamination direction (alternate arrangement direction) is different from that of the light reflecting layer. Specifically, by forming concave portions (groove portions) in a part of the laminated structure and sequentially filling the concave portions (groove portions) with the similar material as the light reflecting layer on the basis of, for example, a sputtering method, a laminated film in which dielectric layers are alternately arranged can be obtained when the laminated film is cut along a virtual plane orthogonal to the lamination direction of the laminated structure. Furthermore, in an aspect in which the outer surface of the laminated film 60 is in contact with the atmosphere, after the end surface including the side parallel to the X direction of the current injection region 51 is exposed by etching or the like the laminated structure or by cutting the laminated structure, by sequentially forming a layer including the similar material as that of the light reflecting layer on the end surface on the basis of, for example, a sputtering method, the laminated film 60 can be obtained. Furthermore, the side parallel to the Y direction of the current injection region 51 may include a line segment or a curve.

In addition, with such a structure, it is possible to suppress the light from being dissipated in the Y direction and to improve the light emission efficiency of the light emitting element. In addition, since the space to the end region of the current injection region can be utilized as the element region, when the area of the element region is the same, a light emitting element having a smaller chip area than that of other Examples can be obtained. For example, in a case where L_{max-Y} is 100 μm and the radius of curvature R₁ of the light field confinement structure (first light reflecting layer having a concave mirror) is 25 μm, applying Modification Example-2 may cause L_{max-Y} to be 50 μm that is a half of L_{max-Y} in order to obtain the same characteristics. As a result, since the substrate area required for manufacturing the light emitting element is halved, the manufacturing cost can be reduced.

### Example 3

Incidentally, in the light emitting elements described in Examples 1 and 2, for example, in a case where a strong external force is applied to the rising part of the first part 91 of the flat base surface 90 for some reason, stress concentrates on the rising part of the first part 91, and there is a concern that damage occurs in the first compound semiconductor layer or the like.

Example 3 is a modification of Examples 1 and 2. FIG. 12 illustrates a schematic partial end view of a light emitting element 10B of Example 3. In Examples 1 and 2, the second part 92 of the base surface 90 is flat. However, in Example 3, with reference to the second surface 21b of the first compound semiconductor layer 21, the second part 92 of the base surface 90 is concave toward the second surface 21b of the first compound semiconductor layer 21. Here, differentiation is possible from the first part 91 to the second part 92. Then, a part where an inflection point exists in the base surface 90 from the first part 91 to the second part 92 is a boundary between the first part 91 and the second part 92. Specifically, the shape “from the peripheral portion to the center portion of the first part/second part” corresponds to the case of (A) described above.

Although the first light reflecting layer 41 is formed in the first part 91 of the base surface 90, the extending portion of the first light reflecting layer 41 may be formed in the second part 92 of the base surface 90 occupying the peripheral region 99, or the first light reflecting layer 41 may not be formed in the second part 92. In Example 3, the first light reflecting layer 41 is not formed in the second part 92 of the base surface 90 occupying the peripheral region 99.

In the light emitting element 10B of Example 3, a boundary 90_{bd} between the first part 91 and the second part 92 can be defined as (1) outer peripheral portion of the first light reflecting layer 41 in a case where the first light reflecting layer 41 does not extend to peripheral region 99, and (2) a part where an inflection point exists in the base surface 90 from the first part 91 to the second part 92 in a case where the first light reflecting layer 41 extends in the peripheral region 99. Here, the light emitting element 10B of Example 3 specifically corresponds to the case of (1).

In the light emitting element 10B of Example 3, the first surface 21a of the first compound semiconductor layer 21 constitutes the base surface 90. The shape drawn by the first part 91 of the base surface 90 when the base surface 90 is cut by a virtual plane (in the illustrated example, for example, the XZ virtual plane) including the lamination direction of the laminated structure 20 can be differentiated, and more specifically, can be a part of a circle, a part of a parabola, a sine curve, a part of an ellipse, a part of a catenary curve, or a combination of these curves, or a part of these curves may be replaced with a line segment. The shape (figure) drawn by the second part 92 can also be differentiated, and more specifically, can be a part of a circle, a part of a parabola, a part of a sine curve, a part of an ellipse, a part of a catenary curve, or a combination of these curves, or a part of these curves may be replaced with a line segment. Furthermore, the boundary between the first part 91 and the second part 92 of the base surface 90 is also differentiable.

In the light emitting element of Example 3, since the base surface has an uneven shape and can be differentiated, and thus in a case where a strong external force is applied to the light emitting element for some reason, it is possible to reliably avoid a problem that stress concentrates on the rising part of the convex portion, and there is no concern that damage occurs in the first compound semiconductor layer or the like. In particular, a light emitting element unit to be described later is connected to and bonded to an external circuit or the like using a bump, but it is necessary to apply a large load (for example, approximately 50 MPa) to the light emitting element unit at the time of bonding. In the light emitting element of Example 3, there is no concern that damage occurs in the light emitting element even when such a large load is applied. In addition, since the base surface has an uneven shape, the occurrence of stray light is further suppressed, and the occurrence of optical crosstalk between the light emitting elements can be more reliably prevented.

Hereinafter, the method for manufacturing the light emitting element of Example 3 will be described.

First, steps similar to [Step—100] to [Step—150] of Example 1 are executed. Thereafter, the first sacrificing layer 81 is formed on the first part 91 of the base surface 90 (specifically, the first surface 21a of the first compound semiconductor layer 21) on which the first light reflecting layer 41 is to be formed, and then the surface of the first sacrificing layer is made convex. Specifically, by forming a first resist material layer on the first surface 21a of the first compound semiconductor layer 21, and patterning the first resist material layer so as to leave the first resist material layer on the first part 91, the first sacrificing layer 81 shown in FIG. 24A is obtained, and then the first sacrificing layer 81 is subjected to heat treatment, and accordingly, the structure illustrated in FIG. 24B can be obtained. Next, when the surface of the first sacrificing layer 81′ is subjected to ashing treatment (plasma irradiation treatment) to alter the surface of the first sacrificing layer 81′, and a second sacrificing layer 82 is formed in the next step, occurrence of damage, deformation, or the like in the first sacrificing layer 81′ is prevented.

Next, the second sacrificing layer 82 is formed on the second part 92 of the base surface 90 exposed between the first sacrificing layer 81′ and the first sacrificing layer 81′ and on the first sacrificing layer 81′ to make the surface of the second sacrificing layer 82 uneven (refer to FIG. 25A). Specifically, the second sacrificing layer 82 including a second resist material layer having an appropriate thickness is formed on the entire surface. Note that, in the example of the arrangement state illustrated in FIG. 12, the average film thickness of the second sacrificing layer 82 is 2 μm, and the average film thickness of the second sacrificing layer 82 is 5 μm.

Alternatively, after the first sacrificing layer 81 is formed on the first surface 21a of the first compound semiconductor layer 21, the surface of the first sacrificing layer 81 is made convex (refer to FIGS. 24A and 24B), thereafter, the first sacrificing layer 81′ is etched back, and further, the first compound semiconductor layer 21 is etched back inward from the first surface 21a, thereby forming a convex portion 91′ with reference to the second surface 21b of the first compound semiconductor layer 21. In this manner, the structure illustrated in FIG. 26A can be obtained. Thereafter, the second sacrificing layer 82 is formed on the entire surface (refer to FIG. 26B).

The material constituting the first sacrificing layer 81 and the second sacrificing layer 82 is not limited to the resist material, and an appropriate material for the first compound semiconductor layer 21 is only required to be selected, such as an oxide material (for example, SiO₂, SiN, TiO₂, or the like), a semiconductor material (for example, Si, GaN, InP, GaAs, or the like), or a metal material (for example, Ni, Au, Pt, Sn, Ga, In, Al, or the like). In addition, by using a resist material having an appropriate viscosity as a resist material constituting the first sacrificing layer 81 and the second sacrificing layer 82, and by appropriately setting and selecting the thickness of the first sacrificing layer 81, the thickness of the second sacrificing layer 82, the diameter of the first sacrificing layer 81′, and the like, the value of the radius of curvature of the base surface 90 and the shape of the unevenness of the base surface 90 (for example, a diameter or a height) can be set to a desired value and shape.

Thereafter, by etching back the second sacrificing layer 82 and the first sacrificing layer 81′ and further etching back from the base surface 90 toward the inside (that is, from the first surface 21a of the first compound semiconductor layer 21 to the inside of the first compound semiconductor layer 21), a convex portion 91a can be formed in the first part 91 of the base surface 90 and at least the concave portion (concave portion 92a in Example 3) can be formed in the second part 92 of the base surface 90 with reference to the second surface 21b of the first compound semiconductor layer 21. In this manner, the structure illustrated in FIG. 25B or 26C can be obtained. In a case where it is necessary to further increase the radius of curvature R₁ of the first part 91 of the base surface 90, this step may be repeated. Etching back can be performed on the basis of a dry etching method such as a RIE method, or can be performed on the basis of a wet etching method using hydrochloric acid, nitric acid, hydrofluoric acid, phosphoric acid, a mixture thereof, or the like.

Next, the first light reflecting layer 41 is formed on the first part 91 of the base surface 90. Specifically, the first light reflecting layer 41 is formed on the entire surface of the base surface 90 on the basis of a film forming method such as a sputtering method or a vacuum deposition method (refer to FIG. 25C), and then the first light reflecting layer 41 is patterned, whereby the first light reflecting layer 41 can be obtained on the first part 91 of the base surface 90 (refer to FIG. 27A). Thereafter, the first electrode 31 common to each light emitting element is formed on the second part 92 of the base surface 90 (refer to FIG. 27B). As described above, the light emitting element unit or the light emitting element 10B of Example 3 can be obtained. When the first electrode 31 protrudes from the first light reflecting layer 41, the first light reflecting layer 41 can be protected. Then, electric connection to an external electrode or circuit (circuit for driving the light emitting element) is only required to be achieved. Specifically, the first compound semiconductor layer 21 is only required to be connected to an external circuit or the like via the first electrode 31 and the first pad electrode (not illustrated), and the second compound semiconductor layer 22 may be connected to an external circuit or the like via the second electrode 32 and the second pad electrode. Next, the light emitting element of Example 3 is completed by packaging or sealing.

### Example 4

Example 4 relates to a light emitting element unit of the present disclosure. FIGS. 13A and 13B schematically illustrate the arrangement state of the current injection region, the current confinement region, and the second electrode in the light emitting element constituting the light emitting element unit of Example 4. In addition, FIG. 14 illustrates a partial end view of the light emitting element unit along the X direction.

The light emitting element unit of Example 4 is a light emitting element unit including a plurality of light emitting elements, and each light emitting element includes the light emitting elements of Examples 1 to 3 including various modification examples. In addition, the plurality of light emitting elements is arranged apart from each other in the X direction. Note that, in the illustrated example, one light emitting element unit is constituted by four light emitting elements, but the number of light emitting elements constituting the light emitting element unit is not limited thereto.

In the light emitting element unit of Example 4, when a width along the Y direction of the current injection region 51 in each light emitting element is L_{max-Y} and a width along the X direction is L_{min-X},

L_{max-Y}/L_{min-X}≥3
is satisfied, and
preferably,

L_{max-Y}/L_{min-X}≥20
is satisfied, and
when an array pitch of the plurality of light emitting elements along the X direction is P_{X},

P_{X}/L_{min-X}≥1.5
is satisfied, and
preferably,

P_{X}/L_{min-X}≥5
is satisfied.

In addition, in the light emitting element unit of Example 4, in the entire light emitting element unit, an emission angle θ_{Y}′ of light in a YZ virtual plane is 2 degrees or less, and an emission angle θ_{X}′ of light in an XZ virtual plane is 0.1 degrees or less.

In addition, in the example illustrated in FIG. 13A, the first electrode 31 is common to the plurality of light emitting elements, and the second electrode 32 is individually provided in each light emitting element. Each of the second electrodes 32 is connected to an external circuit or the like via the second pad electrode (not illustrated). The second pad electrode is provided at a position that does not interfere with emission of light from the light emitting element, and has a structure capable of both emission of light via the first light reflecting layer 41 and emission of light via the second light reflecting layer 42. In some cases, the second pad electrode may be formed so as to cover four light emitting elements (specifically, the second light reflecting layer 42 and the second electrode 32), and may also have a structure in which light is emitted via the first light reflecting layer 41.

Alternatively, in the example illustrated in FIG. 13B, the first electrode 31 is common to a plurality of (four in the illustrated example) light emitting elements, and the second electrode 32 is common to a plurality of (four in the illustrated example) light emitting elements. In other words, the second electrode 32 common to the four light emitting elements is formed so as to cover the second surface 22b of the second compound semiconductor layer 22 in the four light emitting elements, and the second electrode 32 is connected to an external circuit or the like via a second pad electrode (not illustrated). The second pad electrode is provided at a position that does not interfere with emission of light from the light emitting element, and has a structure capable of both emission of light via the first light reflecting layer 41 and emission of light via the second light reflecting layer 42. In some cases, the second pad electrode may be formed so as to cover four light emitting elements (specifically, the second light reflecting layer 42 and the second electrode 32), and may have a structure in which light is emitted via the first light reflecting layer 41. Alternatively, in some cases, instead of the second pad electrode, for example, a transparent conductive material layer including ITO may be formed so as to cover four light emitting elements (specifically, the second light reflecting layer 42 and the second electrode 32), and the second pad electrode may also be connected to the transparent conductive material layer. In this case, it is also possible to have a structure capable of emitting both light via the first light reflecting layer 41 and light via the second light reflecting layer 42.

Specifications of each light emitting element constituting the light emitting element unit are shown in Table 6 below.

TABLE 6

Second pad electrode Ti/Au
Second light reflecting layer 42 SiO₂/Ta₂O₅ (14 pairs)
Second electrode 32 ITO (thickness: 20 nm)
Second compound semiconductor layer 22 p-GaN
(thickness: 130 nm)
Active layer 23 Multiple quantum well structure (total
thickness: 20 nm)
Well layer InGaN (Si-doped: 2 × 10¹⁸ cm⁻³)
Barrier layer GaN
First compound semiconductor layer 21 n-GaN
First light reflecting layer 41 SiO₂/SiN (9 pairs)
First pad electrode V/Pt/Au
λ₀ 445 nm
L_{OR} 25 μm
θ_{Y} 3 degrees or less
θ_{X} 8 degrees
L_{32AB} 50 μm
W_{32AB} 20 μm
r_{32CD} 10 μm
L_{max-Y} 25 μm
L_{min-X} 6 μm
L_{51AB} 25 μm
r_{51CD} —
R₁ 35 μm
R_{91BC} 35 μm
Pₓ 20 μm
θ_{Y}′ 1 degree or less
θ_{X}′ 1 degree or less

In the light emitting elements of Examples 1 and 2, the value of the emission angle in the X direction is large. On the other hand, in the light emitting element unit of Example 4, by arranging the plurality of light emitting elements at the short array pitch P_{X} in the X direction, coherence can be given to the light emitting elements, and coupling between the light emitting elements occurs. As a result, the plurality of light emitting elements constituting the light emitting element unit behaves as if they were one light emitting element, the “uncertainty of the position where the light exists” in the X direction increases, and the emission angle θ_{X}′ in the X direction can be increased as compared with a case of a single light emitting element. In a case of one light emitting element, when the emission angle θx in the X direction is 8 degrees, for example, by arranging four light emitting elements in the same light emitting element, the emission angle θ_{X}′ in the X direction can be suppressed to 0.1 degrees or less.

In addition, for example, when four light emitting elements are arranged, the width of the light emitting element unit in the X direction is 60 μm. When assuming one light emitting element having a width of 60 μm equivalent to such a light emitting element unit, it is necessary to form a single large current injection region. However, the current density becomes non-uniform, the resonator structure of the light emitting element becomes non-uniform, and the coherence of the entire region cannot be maintained. On the other hand, in the light emitting element unit of Example 4, since the distance from the second electrode to each part of the current injection region in each light emitting element is short, a current can be uniformly injected into each light emitting element. Therefore, it is possible to provide a light emitting element having a light field extending over a large region and a light emitting element having a narrow emission angle, which are not possible with a light emitting element having a huge element region having a width of 60 μm. In addition, by individually driving the light emitting elements constituting the light emitting element unit, a desired place or part can be selectively irradiated.

Note that, in the light emitting element unit of Example 4 in which a schematic partial end view is illustrated in FIG. 14, the second part 92 of the base surface 90 is flattened in the X direction and the Y direction. On the other hand, in Modification Example-1 of the light emitting element unit of Example 4 in which a schematic partial end view is illustrated in FIG. 15 along the X direction, the second part 92 of the base surface 90 is concave toward the second surface 21b of the first compound semiconductor layer 21 with reference to the second surface 21b of the first compound semiconductor layer 21 in the X direction and the Y direction similarly in Example 3.

### Example 5

Example 5 relates to the light emitting element according to the second aspect of the present disclosure. A schematic partial end view of the light emitting element of Example 5 is illustrated in FIG. 16, the arrangement state of the current injection region, the current confinement region, and the second electrode constituting the light emitting element of Example 5 is schematically illustrated in (A), (B), (C), and (D) of FIG. 17 and (A) of FIG. 18, and the arrangement state of the current injection region and the current confinement region is schematically illustrated in (B) of FIG. 18. In (B) of FIG. 18, illustration of the second electrode is omitted.

In the light emitting element of Example 5, the planar shape of the current injection region 51 surrounded by the current confinement region 52 includes at least one type of shape (that is, a figure other than a circle) selected from the group consisting of an annular shape, a partially cut annular shape, a shape surrounded by a curve, a shape surrounded by a plurality of line segments, and a shape surrounded by a curve and a line segment. Here, the planar shape of the current injection region 51 may include characters or figures. Note that, unlike the light emitting elements in Examples 1 to 3, the first light reflecting layer 41 is formed on the flat base surface 90.

In the example illustrated in (A) of FIG. 17, the planar shape of the current injection region 51 is an annular shape (ring shape), the annular inner part is occupied by a current confinement region 52A, and the annular outer part is occupied by a current confinement region 52B. The orthographic projection image of the current injection region 51 and the current confinement region 52A is included in the orthographic projection image of the second electrode 32. In addition, the orthographic projection image of the second electrode 32 is included in the orthographic projection image of the current confinement region 52B. The emission angle may be, for example, 5 degrees. The annular shape has an outer diameter, an inner diameter, and a width of 12 μm, 4 μm, and 4 μm, respectively. Note that the outer diameter, the inner diameter, and the width of the partially cut annular shape described below are also 12 μm, 4 μm, and 4 μm, respectively, and the width of the line segment is also 4 μm.

In the example illustrated in (B) of FIG. 17, the planar shape of the current injection region 51 is a partially cut annular shape (“C” shape). The current injection region 51 is surrounded by the current confinement region 52. The orthographic projection image of the current injection region 51 is included in the orthographic projection image of the second electrode 32. In addition, the orthographic projection image of the second electrode 32 is included in the orthographic projection image of the current confinement region 52.

In the examples illustrated in (C) and (D) of FIG. 17 and (A) of FIG. 18, the planar shape of the current injection region 51 is a shape surrounded by a curve and a line segment. Specifically, in the examples illustrated in (C) and (D) of FIG. 17, the shape is a combination of an annular shape and a line segment. In addition, the annular inner part of the current injection region 51 is occupied by the current confinement region 52A, and the annular outer part is occupied by the current confinement region 52B. The orthographic projection image of the current injection region 51, the current confinement region 52A, and the line segment part is included in the orthographic projection image of the second electrode 32. In addition, the orthographic projection image of the second electrode 32 is included in the orthographic projection image of the current confinement region 52B. On the other hand, in the example illustrated in (A) of FIG. 18, the shape is a combination of a partially cut annular shape and a line segment. The current injection region 51 is surrounded by the current confinement region 52. The orthographic projection image of the current injection region 51 is included in the orthographic projection image of the second electrode 32. In addition, the orthographic projection image of the second electrode 32 is included in the orthographic projection image of the current confinement region 52.

In the example illustrated in (B) of FIG. 18, the planar shape of the current injection region 51 is a combination of a plurality of annular shapes. The annular inner part is occupied by the current confinement region 52A, and the annular outer part is occupied by the current confinement region 52B. The orthographic projection image of the current injection region 51 and the current confinement region 52A is included in the orthographic projection image of the second electrode (not illustrated). In addition, the orthographic projection image of the second electrode is included in the orthographic projection image of the current confinement region 52B.

In addition, the planar shape of the current injection region 51 constituting the light emitting element of Example 5 is schematically illustrated in (A), (B), (C), (D), and (E) of FIG. 19, and the planar shape of the current injection region 51 is a character “A” (refer to (A) of FIG. 19), “E” (refer to (B) of FIG. 19), “T” (refer to (C) of FIG. 19), or a figure (for example, a square (refer to (D) of FIG. 19) and a hexagon (refer to (E) of FIG. 19)). In these drawings, illustration of the second electrode and the current confinement region is omitted.

Except for the points different from the structure of the first light reflecting layer 41, the configuration and structure of the light emitting elements of Example 5 can be similar to the configuration and structure of the light emitting element described in Examples 1 and 2, and thus the detailed description thereof will be omitted. Note that the configuration and structure of the light emitting element in Example 5 can be similar to the configuration and structure of the light emitting element including the first light reflecting layer 41 described in Examples 1 to 3.

In the light emitting element of Example 5, the planar shape of the current injection region surrounded by the current confinement region is an annular shape or the like. Specifically, for example, a mirror (concave mirror) having a lens-like structure having a concave cross section is formed through an appropriate optical system, and the light emitting element is arranged on the principal axis of the concave mirror. Accordingly, it is possible to project and visually recognize the light emitted from the light emitting element as a figure or a character, and it is possible to emit and project a light beam having a complicated shape. In addition, by combining a plurality of light emitting elements, it is possible to display, emit, or the like a character string, a plurality of figures, or a combination of characters and figures. In addition, for example, when the planar shape of the current injection region is an annular shape, it is possible to obtain a beam having a narrow emission angle of the same degree with a smaller current amount and power than in a case where the planar shape of the current injection region is a circular shape, and furthermore, it is possible to suppress heat generation, and the reliability is also improved.

### Example 6

Example 6 is a modification of Examples 1 to 5. In Examples 1 to 5, the laminated structure 20 includes a GaN-based compound semiconductor. On the other hand, in Example 6, the laminated structure 20 includes an InP-based compound semiconductor or a GaAs-based compound semiconductor. As an example, the specifications of the light emitting element in the light emitting element (however, the laminated structure 20 includes an InP-based compound semiconductor) in the light emitting element having the configuration of Example 2 illustrated in FIG. 9 are shown in Table 7 below. In addition, the specifications of the light emitting element in the light emitting element (however, the laminated structure 20 includes a GaAs-based compound semiconductor) in the light emitting element having the configuration of Example 2 illustrated in FIG. 9 are shown in Table 8 below.

TABLE 7

Second light reflecting layer 42
SiO₂/Ta₂O₅ (8 pairs)
or
AlInGaAsP layer or
AlInGaAsSb layer
Second electrode 32 Ti/Pt/Au
Second compound semiconductor layer 22 p-InP
Active layer 23
Well layer AlGaInAs (multiple quantum well
structure)
(λ₀: 1.0 μm to 1.6 μm)
or
InGaAsP (multiple quantum well
structure)
(λ₀: 1.0 μm to 1.6 μm)
or
InAs quantum dot (λ₀: 1.2 μm to 1.8 μm)
GaInAsP
Barrier layer
or
AlGaInAs
First compound semiconductor layer 21 n-InP
First light reflecting layer 41 SiO₂/SiN (10 pairs)
Substrate Undoped InP substrate
or
InP substrate with doping amount of 1 × 10¹⁸
cm⁻³ or less
λ₀ 1.4 μm
L_{OR} 10 μm
θ_{Y} 10 degrees or less
θ_{X} 30 degrees
L_{32AB} 50 μm
W_{32AB} 20 μm
r_{32CD} 10 μm
L_{max-Y} 25 μm
L_{min-X} 6 μm
L_{51AB} 25 μm
r_{51CD} 5 μm
R₁ 15 μm
R_{91BC} 15 μm
Pₓ 20 μm
θ_{Y}′ 1 degree or less
θ_{X}′ 1 degree or less

TABLE 8

Second light reflecting layer 42 p-AlGaAs (28 pairs)
or
SiO₂/Ta₂O₅ (11.5 pairs)
Second electrode 32 Ti/Pt/Au
Second compound semiconductor layer 22 p-GaAs
Active layer 23 GaInAs (multiple quantum well
structure)
(λ₀: 0.85 μm to 1.2 μm)
or
GaInNAs (multiple quantum well
structure)
(λ₀: 1.2 μm to 1.5 μm)
or
InAs quantum dot
(λ₀: 1.2 μm to 1.5 μm)
Barrier layer GaAs
First compound semiconductor layer 21 n-GaAs
First light reflecting layer 41 SiO₂/SiN (10 pairs)
λ₀ 1.4 μm
L_{OR} 10 μm
θ_{Y} 10 degrees or less
θ_{X} 31 degrees
L_{32AB} 50 μm
W_{32AB} 20 μm
r_{32CD} 10 μm
L_{max-Y} 25 μm
L_{min-X} 6 μm
L_{51AB} 25 μm
r_{51CD} 5 μm
R₁ 15 μm
R_{91BC} 15 μm
Pₓ 20 μm
θ_{Y}′ 1 degree or less
θ_{X}′ 1 degree or less

The configuration and structure of the light emitting element of Example 6 can be similar to those of the light emitting elements of Examples 1 to 3 and 5 except that the configuration of the laminated structure is different, and the configuration and structure of the light emitting element unit using the light emitting element of Example 6 can be similar to those of the light emitting element unit of Example 4.

### Example 7

Example 7 is a modification of Examples 1 to 6.

Incidentally, when an equivalent refractive index of the entire laminated structure is n_{eq}, and a wavelength of laser light to be emitted from a surface light emitting laser element (light emitting element) is λ₀, the resonator length L_{OR} in the laminated structure including the two DBR layers and the laminated structure formed therebetween is expressed by L=(m·λ₀)/(2·n_{eq}). Here, m is a positive integer. Then, in the surface light emitting laser element (light emitting element), the wavelength at which the oscillation is possible is determined by the resonator length L_{OR}. Each oscillation mode in which oscillation is possible is called a longitudinal mode. Then, among the longitudinal modes, a mode that matches the gain spectrum determined by the active layer can cause laser oscillation. When the effective refractive index is n_{eff}, an interval Δλ between the longitudinal modes is expressed by λ₀²/(2n_{eff}·L). In other words, the longer the resonator length L_{OR}, the narrower the interval Δλ between the longitudinal modes. Therefore, in a case where the resonator length L_{OR} is long, a plurality of longitudinal modes may exist in the gain spectrum, and thus oscillation is possible in a plurality of longitudinal modes. Note that the equivalent refractive index nₑg and the effective refractive index n_{eff} have the following relationship when the oscillation wavelength is λ₀.

n_{eff}=n_{eq}−λ₀·(dn_{eq}/dλ₀)

Here, in a case where the laminated structure includes a GaAs-based compound semiconductor layer, the resonator length L_{OR} is usually as short as 1 μm or less, and the laser light in the longitudinal mode which is emitted from the surface light emitting laser element is one type (one wavelength) (refer to the conceptual diagram of FIG. 29A). Therefore, it is possible to accurately control the oscillation wavelength of the laser light in the longitudinal mode emitted from the surface light emitting laser element. On the other hand, in a case where the laminated structure includes a GaN-based compound semiconductor layer, the resonator length L_{OR} is usually as long as several times the wavelength of the laser light emitted from the surface light emitting laser element. Therefore, there are a plurality of types of laser light in the longitudinal mode that can be emitted from the surface light emitting laser element (refer to the conceptual diagram of FIG. 29B), and it becomes difficult to accurately control the oscillation wavelength of the laser light that can be emitted from the surface light emitting laser element.

As illustrated in the schematic partial cross-sectional view in FIG. 20, in a light emitting element 10C of Example 7 or the light emitting elements of Examples 8 and 9 described later, in the laminated structure 20 including the second electrode 32, at least two light absorbing material layers 26, preferably at least four light absorbing material layers 26, and specifically twenty light absorbing material layers 26 in Example 7 are formed in parallel with the virtual plane (XY virtual plane) occupied by the active layer 23. Note that, in order to simplify the drawing, only one light absorbing material layer 26 is illustrated in the drawing.

In Example 7, the oscillation wavelength (as will be desired oscillation wavelength emitted from the light emitting element) λ₀ is 450 nm. The twenty light absorbing material layers 26 include a compound semiconductor material having a band gap narrower than that of the compound semiconductor constituting the laminated structure 20, specifically, n-In_{0.2}Ga_{0.8}N, and are formed inside the first compound semiconductor layer 21. The thickness of the light absorbing material layer 26 is λ₀/(4·n_{eq}) or less, specifically, 3 nm. In addition, the light absorption coefficient of the light absorbing material layer 26 is 2 times or more, specifically, 1×10³ times the light absorption coefficient of the first compound semiconductor layer 21 including the n-GaN layer.

In addition, the light absorbing material layer 26 is positioned at the minimum amplitude part generated in a standing wave of light formed inside the laminated structure, and the active layer 23 is positioned at the maximum amplitude part generated in a standing wave of light formed inside the laminated structure. The distance between the center of the active layer 23 in the thickness direction and the center of the light absorbing material layer 26 adjacent to the active layer 23 in the thickness direction is 46.5 nm. Furthermore, when an equivalent refractive index of all of the two light absorbing material layers 26 and a part of the laminated structure positioned between the light absorbing material layers 26 and 26 (specifically, in Example 7, the first compound semiconductor layer 21) is n_{eq}, and a distance between the light absorbing material layers 26 and 26 is L_{Abs}, 0.9× {(m·λ₀)/(2·n_{eq})}≤L_{Abs}≤1.1× {(m·λ₀)/(2·n_{eq})} is satisfied. Here, m is 1 or any integer of 2 or more including 1. However, in Example 7, m=1 was satisfied. Therefore, the distance between the adjacent light absorbing material layers 26 satisfies 0.9× {λ₀/(2·n_{eq})}≤L_{Abs}≤1.1× {λ₀/(2·n_{eq})} in all of the plurality of light absorbing material layers 26 (twenty light absorbing material layers 26). The value of the equivalent refractive index n_{eq} is specifically 2.42, and when m=1, specifically, L_{Abs}=1×450/(2×2.42)=93.0 nm is satisfied. Note that, in some of the light absorbing material layers 26 among the twenty light absorbing material layers 26, m may be any integer of 2 or more.

In the manufacture of the light emitting element of Example 7, the laminated structure 20 is formed in the similar step as [Step—100] of Example 1, and at this time, the twenty light absorbing material layers 26 are also formed inside the first compound semiconductor layer 21. Except for this point, the light emitting element of Example 7 can be manufactured on the basis of the similar method as that of the light emitting element of Example 5.

A case where a plurality of longitudinal modes occurs in the gain spectrum determined by the active layer 23, is schematically illustrated in FIG. 28. Note that FIG. 28 illustrates two longitudinal modes, a longitudinal mode A and a longitudinal mode B. Then, in this case, it is assumed that the light absorbing material layer 26 is positioned in the minimum amplitude part of the longitudinal mode A and is not positioned in the minimum amplitude part of the longitudinal mode B. Then, the mode loss of the longitudinal mode A is minimized, but the mode loss of the longitudinal mode B is large. In FIG. 28, the mode loss amount of the longitudinal mode B is schematically indicated by a solid line. Therefore, oscillation is more likely to occur in the longitudinal mode A than in the longitudinal mode B. Therefore, by using such a structure, that is, by controlling the position and period of the light absorbing material layer 26, a specific longitudinal mode can be stabilized and oscillation can be facilitated. On the other hand, since it is possible to increase the mode loss with respect to the other undesirable longitudinal modes, it is possible to suppress the oscillation of the other undesirable longitudinal modes.

As described above, in the light emitting element of Example 7, since at least two light absorbing material layers are formed inside the laminated structure, undesired oscillation of laser light in the longitudinal mode in the laser light of a plurality of types of longitudinal modes, which can be emitted from the surface light emitting laser element, can be suppressed. As a result, the oscillation wavelength of the emitted laser light can be accurately controlled. Moreover, since the light emitting element of Example 7 has the first part, occurrence of diffraction loss can be reliably suppressed.

### Example 8

Example 8 is a modification of Example 7. In Example 7, the light absorbing material layer 26 was made of a compound semiconductor material having a band gap narrower than that of the compound semiconductor constituting the laminated structure 20. On the other hand, in Example 8, ten light absorbing material layers 26 were made of a compound semiconductor material doped with impurities, specifically, a compound semiconductor material (specifically, n-GaN:Si) having an impurity concentration (impurity: Si) of 1×10¹⁹/cm³. Further, in Example 8, the oscillation wavelength λ₀ was set to 515 nm. Note that the composition of the active layer 23 is In_{0.3}Ga_{0.7}N. In Example 8, m=1, the value of L_{Abs} is 107 nm, the distance between the center of the active layer 23 in the thickness direction and the center of the light absorbing material layer 26 adjacent to the active layer 23 in the thickness direction is 53.5 nm, and the thickness of the light absorbing material layer 26 is 3 nm. Except for the above points, the configuration and structure of the light emitting element of Example 8 can be similar to the configuration and structure of the light emitting element described in Example 7, and thus the detailed description thereof will be omitted. Note that, in some of the light absorbing material layers 26 among the ten light absorbing material layers 26, m may be any integer of 2 or more.

### Example 9

Example 9 is also a modification of Example 7. In Example 9, five light absorbing material layers (referred to as “first light absorbing material layer” for convenience) were configured similarly to the light absorbing material layer 26 of Example 7, that is, including n-In_{0.3}Ga_{0.7}N. Furthermore, in Example 9, one light absorbing material layer (referred to as “second light absorbing material layer” for convenience) was made of a transparent conductive material. Specifically, the second light absorbing material layer was also used as the second electrode 32 including ITO. In Example 9, the oscillation wavelength λ₀ was set to 450 nm. In addition, m was set to 1 and 2. When m=1, the value of L_{Abs} is 93.0 nm, the distance between the center of the active layer 23 in the thickness direction and the center of the first light absorbing material layer adjacent to the active layer 23 in the thickness direction is 46.5 nm, and the thickness of five first light absorbing material layer is 3 nm. In other words, in the five first light absorbing material layers, 0.9× {λ₀/(2·n_{eq})}≤L_{Abs}≤1.1× {λ₀/(2·n_{eq})} is satisfied. In addition, the first light absorbing material layer and the second light absorbing material layer adjacent to the active layer 23 satisfied m=2. In other words, 0.9× {2·λ₀/(2·n_{eq})}≤L_{Abs}≤1.1× {(2·λ₀)/(2·n_{eq})} is satisfied. One second light absorbing material layer that also serves as the second electrode 32 has a light absorption coefficient of 2000 cm⁻¹ and a thickness of 30 nm, and the distance from the active layer 23 to the second light absorbing material layer is 139.5 nm. Except for the above points, the configuration and structure of the light emitting element of Example 9 can be similar to the configuration and structure of the light emitting element described in Example 7, and thus the detailed description thereof will be omitted. Note that, in some of the first light absorbing material layers among the five first light absorbing material layers, m may be any integer of 2 or more. Note that, unlike Example 7, the number of light absorbing material layers 26 may be 1. Also in this case, the positional relationship between the second light absorbing material layer that also serves as the second electrode 32 and the light absorbing material layer 26 needs to satisfy the following expression.

0.9×{(m·λ₀)/(2·n_{eq})}≤L_{Abs}≤1.1×{(m·λ₀)/(2·n_{eq})}

### Example 10

Example 10 relates to an electronic device or a light emitting device. The electronic device or the light emitting device of Example 10 includes the light emitting elements of Examples 1 to 3 and 5 or the light emitting element unit of Example 4. In addition, specifically, the light emitting elements of Examples 1 to 3 and 5 and the light emitting element unit of Example 4 can be incorporated in electronic devices such as various display devices such as a projector, a television receiver, and a monitor, pixels constituting a display device, indoor and outdoor lighting, a laser pointer, a level using a laser, and a distance measuring device, for example. The electronic device itself is only required to have a known configuration and structure.

Alternatively, a light emitting device (or an illumination device) can also include the light emitting elements of Examples 1 to 3 and 5 and the light emitting element unit of Example 4 described above. For example, as illustrated in (A) of FIG. 17, the light emitting device (specifically, for example, a headlight or the like) in which the planar shape of the current injection region 51 is an annular shape (ring shape) can be mounted on various moving objects such as a vehicle including an automobile, a motorcycle, and a bicycle. For example, 24 μm, 12 μm, and 6 μm can be exemplified as the outer diameter, the inner diameter, and the width of the annular shape. The cross-sectional shape of the emitted light immediately after being emitted from the light emitting element is an annular shape, but becomes circular or the like at a position sufficiently far from the light emitting element, and a light beam having high quality can be obtained.

Alternatively, a light emitting device (or an illumination device) in a device such as a light source unit of a line sensor, a light source unit of a two-dimensional line sensor by multi-processing, a Li-Hi light source unit capable of corresponding to a wider region at a higher speed, and a laser processing light source unit capable of processing a wider region, can be used. Furthermore, the light emitting device can be incorporated in various display devices. The light emitting device, the illumination device, the display device, and the devices themselves are only required to have known configurations and structures.

The oscillation wavelength (emission wavelength) λ₀ of the light emitting element may be, for example, 400 nm to 500 nm, or when a wavelength conversion material layer (color conversion material layer) to be described later is provided, light having a desired color can be emitted.

In the light emitting device (or the illumination device) of Example 10, the emission angle is smaller (narrower) than that of a normally used end surface light emitting laser element (or surface light emitting laser element). Then, since a light beam having a narrow emission angle spreading around the light emitting device (or the illumination device) can be obtained without an external optical system (external optical component) (or only with a simple optical component), weight reduction, cost reduction, and high reliability of the entire device can be obtained.

In addition, a light emitting device (or an illumination device) may be used as a light source, and for example, a desired object, part, place, or the like may be irradiated with light using an optical fiber. In this case, light emitted from the light emitting element can be efficiently coupled to the optical fiber, and thus reduction in power consumption and long life can be realized.

Note that the electronic device or the light emitting device of Example 10 and the sensing device of Example 11 described later may include a plurality of types of the light emitting elements of Example 5. In other words, the electronic device or the light emitting device, and the sensing device may be configured by mixing the light emitting elements in which the planar shape of the current injection region described in Example 5 includes at least one type of shape selected from the group consisting of an annular shape, a partially cut annular shape, a shape surrounded by a curve, a shape surrounded by a plurality of line segments, and a shape surrounded by a curve and a line segment. Then, the irradiation pattern is changed by individually and appropriately driving each light emitting element.

### Example 11

Example 11 relates to a sensing device. The sensing device of Example 11 includes: a light exit device including the light emitting elements of Examples 1 to 3 and 5 or the light emitting element unit of Example 4; and a light receiving device that receives light emitted from the light exit device. The sensing device itself is only required to have a known configuration and structure.

Specific examples of the sensing device include light detection and ranging (LIDAR). Alternatively, the light exit device can be used to emit structured light in a three-dimensional sensing device by a method of measuring the distance to the subject or measuring a three-dimensional shape of the subject in a non-contact manner, and for example, structured light based on infrared rays is only required to be emitted to irradiate the subject. Examples of the structured light include a line-and-space pattern, a lattice pattern, and a dot pattern, and these patterns are only required to be emitted from the light exit device including the light emitting elements of Examples 1 to 3 and 5 or the light emitting element unit of Example 4, for example. Alternatively, when a light emitting element in which a cross-sectional shape of emitted light is a “rod shape” or an “I shape” extending in the Y direction described in Example 1 is used as a light exit device of a sensing device, and is attached to a place where the light exit device is to be sensed with the Y direction as a vertical direction or various moving objects such as a vehicle including an automobile, a motorcycle, and a bicycle, it becomes possible to widely emit light in the horizontal direction, and it becomes possible to sense a wide region in the horizontal direction. Alternatively, examples of the sensing device can include a mobile image display, a communication apparatus, and a smartphone.

### Example 12

Example 12 relates to a communication device. The communication device of Example 12 includes: a light exit device including a plurality of types of the light emitting elements of Example 5; and a light receiving device that receives light emitted from the light exit device.

Here, the light exit device including the plurality of types of light emitting elements of Example 5 refers to a light exit device configured by mixing the light emitting elements in which the planar shape of the current injection region described in Example 5 includes at least one type of shape selected from the group consisting of an annular shape, a partially cut annular shape, a shape surrounded by a curve, a shape surrounded by a plurality of line segments, and a shape surrounded by a curve and a line segment. In other words, the light exit device refers to a light exit device in which a plurality of different-shaped light sources (a plurality of light emitting elements having different cross-sectional shapes of emitted light) is mounted.

Then, a diffractive optical element (DOE) is arranged between the light exit device and the light receiving device. Furthermore, an optical element such as a lens may be arranged. The irradiation pattern is changed by individually and appropriately driving each light emitting element. The light reaching the light receiving device changes depending on the configuration, form, shape, and performance of the external optical system (external optical component) such as the DOE, the relative position with respect to the light exit device, the light emission patterns of the plurality of types of light emitting elements constituting the light exit device, the cross-sectional shape of the light emitted from the light exit device, the driving conditions of the light exit device and the light emitting element, which light emitting element among the plurality of light emitting elements in the light exit device blinks is acquired as a signal (hereinafter these are collectively referred to as “parameters”), and the like. When the light emitted from the light exit device reaches the light receiving device, in a case where the parameter is unknown, it is not possible to know how the light emitted from the light exit device changes. Therefore, the communication device of Example 12 can constitute one type of cryptographic communication system using all or some of these parameters as a composite key.

In other words, in normal spatial communication (or visible light communication), information is given (encoded) to blinking of the light source, and the information is transmitted to a distant place. However, in this case, when the light receiving element is arranged in a region irradiated with light, the information can be acquired. In other words, wiretapping can be easily performed. On the other hand, in the communication device of Example 12, a third party who does not know the above parameters cannot know the information included in the blinking of the light emitting element. Therefore, these parameters can be used as an encryption transmission and communication system using a composite key, and when using the communication device of Example 12, it becomes possible to transmit information to a distant place more firmly than in a case where a single light emitting element is simply blinked. In other words, blinking of a specific pattern can be encrypted and used for spatial transmission, and private communication can be performed in a public space using visible light spatial communication or the like. Furthermore, when a plurality of patterns is transmitted to a distant place, the present disclosure can be applied to communication in which information unique to each pattern is added, similarly to PAM4 in optical communication.

Although the present disclosure has been described above on the basis of preferred Examples, the present disclosure is not limited to these Examples. The configuration and structure of the light emitting element described in Examples are examples, and can be appropriately changed, and the method for manufacturing the light emitting element can also be appropriately changed. In some cases, by appropriately selecting the bonding layer and the support substrate, a surface light emitting laser element that emits light from the second surface of the second compound semiconductor layer via the second light reflecting layer can be obtained. Further, in some cases, a through-hole reaching the first compound semiconductor layer can be formed in a region of the second compound semiconductor layer and the active layer that do not affect light emission, and a first electrode insulated from the second compound semiconductor layer and the active layer can be formed in the through-hole. The first light reflecting layer may extend to the second part of the base surface. In other words, the first light reflecting layer on the base surface may include a so-called solid film. Then, in this case, a through-hole may be formed in the first light reflecting layer extending in the second part of the base surface, and the first electrode connected to the first compound semiconductor layer is only required to be formed in the through-hole. Further, a base surface can also be formed by providing a sacrificing layer on the basis of a nanoimprint method. Although the first light reflecting layer is formed on the convex portion of the base surface except for Example 5, the first light reflecting layer may be formed on a flat base surface in each Example.

In order to control the polarization state of the light emitted from the light emitting element, a plurality of groove portions extending in one direction (X direction or Y direction) may be formed in the second electrode.

A wavelength conversion material layer (color conversion material layer) may be provided in a region of the light emitting element from which light is emitted. Then, in this case, white light may be emitted via the wavelength conversion material layer (color conversion material layer). Specifically, in a case where the light emitted from the active layer is emitted to the outside via the first light reflecting layer, a wavelength conversion material layer (color conversion material layer) may be formed on the light emitting side of the first light reflecting layer, and in a case where light emitted from the active layer is emitted to the outside via the second light reflecting layer, a wavelength conversion material layer (color conversion material layer) is only required to be formed on the light emitting side of the second light reflecting layer.

In a case where blue light is emitted from the light emitting layer, white light may be emitted via the wavelength conversion material layer by adopting the following aspects.

[A] By using a wavelength conversion material layer that converts blue light emitted from the light emitting layer into yellow light, white light in which blue and yellow are mixed is obtained as light emitted from the wavelength conversion material layer.
[B] By using a wavelength conversion material layer that converts blue light emitted from the light emitting layer into orange light, white light in which blue and orange are mixed is obtained as light emitted from the wavelength conversion material layer.
[C] By using a wavelength conversion material layer that converts blue light emitted from the light emitting layer into green light and a wavelength conversion material layer that converts blue light into red light, white light in which blue, green, and red are mixed is obtained as light emitted from the wavelength conversion material layer.

Alternatively, in a case where ultraviolet rays are emitted from the light emitting layer, white light may be emitted via the wavelength conversion material layer by adopting the following aspects.

[D] By using a wavelength conversion material layer that converts ultraviolet rays emitted from the light emitting layer into blue light and a wavelength conversion material layer that converts ultraviolet rays into yellow light, white light in which blue and yellow are mixed is obtained as light emitted from the wavelength conversion material layer.
[E] By using a wavelength conversion material layer that converts ultraviolet rays emitted from the light emitting layer into blue light and a wavelength conversion material layer that converts ultraviolet rays into orange light, white light in which blue and orange are mixed is obtained as light emitted from the wavelength conversion material layer.
[F] By using a wavelength conversion material layer that converts ultraviolet rays emitted from the light emitting layer into blue light, a wavelength conversion material layer that converts ultraviolet rays into green light, and a wavelength conversion material layer that converts ultraviolet rays into red light, white light in which blue, green, and red are mixed is obtained as light emitted from the wavelength conversion material layer.

Here, examples of the wavelength conversion material which is excited by blue light and emits red light include, specifically, red light emitting phosphor particles, and more specifically, (ME:Eu)S (here, “ME” means at least one type of atom selected from the group consisting of Ca, Sr, and Ba, and the similar applies below), (M:Sm)ₓ(Si,Al)₁₂(O, N)₁₆ (here, “M” means at least one type of atom selected from the group consisting of Li, Mg, and Ca, and the similar applies below), ME₂Si₅N₈:Eu, (Ca:Eu)SiN₂, and (Ca:Eu)AlSiN₃. Further, examples of the wavelength conversion material which is excited by blue light and emits green light include, specifically, green light emitting phosphor particles, and more specifically, (ME:Eu)Ga₂S₄, (M:RE)ₓ(Si,Al)₁₂(O,N)₁₆ (here, “RE” means Tb and Yb), (M:Tb)ₓ(Si, Al)₁₂(O,N)₁₆, (M:Yb)ₓ(Si,Al)₁₂(O,N)₁₆, and Si_{6-z} Al_{z}O_{z}N_{8-z}:Eu. Furthermore, examples of the wavelength conversion material which is excited by blue light and emits yellow light include, specifically, yellow light emitting phosphor particles, and more specifically, yttrium aluminum garnet (YAG) based phosphor particles. Note that the wavelength conversion material may be used alone or in combination of two or more types thereof. Furthermore, by using a mixture of two or more types of wavelength conversion materials, emitted light of colors other than yellow, green, and red can also be emitted from the wavelength conversion material mixture. Specifically, for example, cyan color may be emitted, and in this case, a mixture of the green light emitting phosphor particles (for example, LaPO₄:Ce,Tb, BaMgAl₁₀O₁₇:Eu,Mn, Zn₂SiO₄:Mn, MgAl₁₁O₁₉:Ce,Tb, Y₂SiO₅:Ce,Tb, and MgAl₁₁O₁₉:CE,Tb,Mn) and the blue light emitting phosphor particles (for example, BaMgAl₁₀O₁₇:Eu, BaMg₂Al₁₆O₂₇:Eu, Sr₂P₂O₇:Eu, Sr₅ (PO₄)₃Cl:Eu, (Sr,Ca,Ba,Mg)₅(PO₄)₃Cl:Eu, CaWO₄, and CaWO₄:Pb) may be used.

Further, examples of the wavelength conversion material which is excited by ultraviolet rays and emits red light include, specifically, red light emitting phosphor particles, and more specifically, Y₂O₃:Eu, YVO₄:Eu, Y(P,V)O₄:Eu, 3.5MgO·0.5MgF₂·Ge₂:Mn, CaSiO₃:Pb,Mn, Mg₆AsO₁₁:Mn, (Sr, Mg)₃ (PO₄)₃:Sn, La₂O₂S:Eu, and Y₂O₂S:Eu. Further, examples of the wavelength conversion material which is excited by ultraviolet rays and emits green light include, specifically, green light emitting phosphor particles, and more specifically, LaPO₄:Ce,Tb, BaMgAl₁₀O₁₇:Eu,Mn, Zn₂SiO₄:Mn, MgAl₁₁O₁₉:Ce,Tb, Y₂SiO₅:Ce,Tb, MgAl₁₁O₁₉:CE,Tb,Mn, and Si_{6-z}Al_{z}O_{z}N_{8-z}:Eu. Furthermore, examples of the wavelength conversion material which is excited by ultraviolet rays and emits blue light include, specifically, blue light emitting phosphor particles, and more specifically, BaMgAl₁₀O₁₇:Eu, BaMg₂Al₁₆O₂₇:Eu, Sr₂P₂O₇:Eu, Sr₅ (PO₄)₃Cl:Eu, (Sr, Ca, Ba, Mg) (PO₄)₃Cl:Eu, CaWO₄, and CaWO₄:Pb. Furthermore, examples of the wavelength conversion material which is excited by ultraviolet rays and emits yellow light include, specifically, yellow light emitting phosphor particles, and more specifically, YAG based phosphor particles. Note that the wavelength conversion material may be used alone or in combination of two or more types thereof. Furthermore, by using a mixture of two or more types of wavelength conversion materials, emitted light of colors other than yellow, green, and red can also be emitted from the wavelength conversion material mixture. Specifically, cyan color may be emitted, and in this case, a mixture of the green light emitting phosphor particles and the blue light emitting phosphor particles described above may be used.

However, the wavelength conversion material (color conversion material) is not limited to phosphor particles. For example, in an indirect transition type silicon-based material, in order to efficiently convert carriers into light as in a direct transition type, light emitting particles to which a wave function of carriers is localized and a quantum well structure such as a two-dimensional quantum well structure, a one-dimensional quantum well structure (quantum fine wire), or a zero-dimensional quantum well structure (quantum dot) using a quantum effect is applied can be exemplified. Rare earth atoms added to a semiconductor material are known to sharply emit light by in-shell transition, and light emitting particles to which such a technology is applied can also be exemplified.

Examples of the wavelength conversion material (color conversion material) include quantum dots as described above. As the size (diameter) of the quantum dot decreases, the band gap energy increases, and the wavelength of light emitted from the quantum dot decreases. In other words, as the size of the quantum dot is smaller, light having a shorter wavelength (light on the blue light side) is emitted, and as the size is larger, light having a longer wavelength (light on the red light side) is emitted. Therefore, it is possible to obtain a quantum dot that emits light having a desired wavelength (performs color conversion to a desired color) by using the same material constituting the quantum dot and adjusting the size of the quantum dot. Specifically, the quantum dot preferably has a core-shell structure. Examples of a material constituting the quantum dot include Si; Se; CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, AgInSe₂ which are chalcopyrite-based compounds; perovskite-based material; and GaAs, GaP, InP, InAs, InGaAs, AlGaAs, InGaP, AlGaInP, InGaAsP, and GaN which are group III-V compounds; and CdSe, CdSeS, CdS, CdTe, In₂Se₃, In₂S₃, Bi₂Se₃, Bi₂S₃, ZnSe, ZnTe, ZnS, HgTe, HgS, PbSe, PbS, TiO₂, and the like, but are not limited thereto.

Note that the present disclosure can also have the following configurations.

### [A01]<<Light Emitting Element: First Aspect>>

A light emitting element including:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer, in which
a current confinement region that controls an inflow of a current to the active layer is provided, and
when an axis in a thickness direction of the laminated structure passing through a center of a current injection region surrounded by the current confinement region is defined as a Z axis, a direction orthogonal to the Z axis is defined as an X direction, and a direction orthogonal to the X direction and the Z axis is defined as a Y direction, the current injection region has an elongated planar shape in which a longitudinal direction extends in the Y direction.
   [A02] The light emitting element according to [A01], in which
when a width of the current injection region along the Y direction is L_{max-Y} and a width along the X direction is L_{min-X},

L_{max-Y}/L_{min-X}≥3
is satisfied.
   [A03] The light emitting element according to [A01] or [A02], in which
the first light reflecting layer has a convex shape toward a direction away from the active layer, and
the second light reflecting layer has a flat shape.
   [A04] The light emitting element according to any one of [A01] to [A03], in which a planar shape of the first light reflecting layer is a shape approximating the planar shape of the current injection region.
   [A05] The light emitting element according to any one of [A01] to [A04], in which an emission angle of light in a YZ virtual plane is 2 degrees or less.
   [A06] The light emitting element according to any one of [A01] to [A05], in which a planar shape of the current injection region is an oval shape.
   [A07] The light emitting element according to any one of [A01] to [A05], in which a planar shape of the current injection region is a rectangular shape.
   [A08] The light emitting element according to [A07], in which an end surface including a side parallel to the X direction of the current injection region is in contact with a layer in which a first dielectric layer and a second dielectric layer are alternately arranged in the Y direction.
   [A09] The light emitting element according to any one of [A06] to [A08], in which a side parallel to the Y direction of the current injection region includes a line segment or a curve.

### [A10]<<Light Emitting Element: Second Aspect>>

A light emitting element including:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface
are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer, in which
a current confinement region that controls an inflow of a current to the active layer is provided, and
a planar shape of the current injection region surrounded by the current confinement region includes at least one type of shape selected from a group consisting of an annular shape, a partially cut annular shape, a shape surrounded by a curve, a shape surrounded by a plurality of line segments, and a shape surrounded by a curve and a line segment.
   [A11] The light emitting element according to [A10], in which the planar shape of the current injection region includes characters or figures.
   [A12] The light emitting element according to any one of [A01] to [C11], in which the laminated structure includes at least one type of material selected from the group consisting of a GaN-based compound semiconductor, an InP-based compound semiconductor, and a GaAs-based compound semiconductor.
   [A13] The light emitting element according to any one of [A01] to [A12], in which the compound semiconductor substrate is disposed between the first surface of the first compound semiconductor layer and the first light reflecting layer, and the base surface includes the surface of the compound semiconductor substrate.
   [A14] The light emitting element according to any one of [A01] to [A12], in which the base material is disposed between the first surface of the first compound semiconductor layer and the first light reflecting layer, or the compound semiconductor substrate and the base material is disposed between the first surface of the first compound semiconductor layer and the first light reflecting layer, and the base surface includes the surface of the base material.
   [A15] The light emitting element according to [A14], in which a material constituting the base material is at least one type of material selected from the group consisting of a transparent dielectric material such as TiO₂, Ta₂O₅, or SiO₂, a silicone-based resin, and an epoxy-based resin.
   [A16] The light emitting element according to any one of [A01] to [A15], in which
the first light reflecting layer is formed on the base surface positioned on the first surface side of the first compound semiconductor layer, and
the base surface has an uneven shape and is differentiable.
   [A17] The light emitting element according to [A16], in which the base surface is smooth.
   [A18] The light emitting element according to [A16] or [A17], in which the first part of a base surface on which the first light reflecting layer is formed has an upward convex shape with reference to the second surface of the first compound semiconductor layer.
   [A19] The light emitting element according to [A18], in which the second part of the base surface occupying the peripheral region has a downward convex shape with reference to the second surface of the first compound semiconductor layer.
   [A20] The light emitting element according to any one of [A16] to [A19], in which a shape (figure) drawn by the first part of the base surface when the base surface is cut along a virtual plane including the lamination direction of the laminated structure is a part of a circle or a part of a parabola.
   [A21] The light emitting element according to any one of [A16] to [A20], in which the first surface of the first compound semiconductor layer constitutes the base surface.
   [A22] The light emitting element according to any one of [A16] to [A21], in which the first light reflecting layer is formed on the base surface.
   [A23] The light emitting element according to any one of [A01] to [A22], in which at least two light absorbing material layers are formed in parallel with the virtual plane occupied by the active layer in the laminated structure including the second electrode.
   [A24] The light emitting element according to [A23], in which at least four light absorbing material layers are formed.
   [A25] The light emitting element according to [A23] or [A24], in which, when an oscillation wavelength is λ₀, and an equivalent refractive index of all of the two light absorbing material layers and a part of the laminated structure positioned between the light absorbing material layers is n_{eq}, and a distance between the light absorbing material layers is L_{Abs},

0.9×{(m·λ₀)/(2·n_{eq})}≤L_{Abs}≤1.1×{(m·λ₀)/(2·n_{eq})}
is satisfied.

Here, m is 1 or any integer of 2 or more including 1.

[A26] The light emitting element according to any one of [A23] to [A25], in which the light absorbing material layer has a thickness of λ₀/(4·n_{eq}) or less.
[A27] The light emitting element according to any one of [A23] to [A26], in which the light absorbing material layer is positioned in a minimum amplitude part generated in a standing wave of light formed inside the laminated structure.
[A28] The light emitting element according to any one of [A23] to [A27], in which the active layer is positioned in a minimum amplitude part generated in a standing wave of light formed inside the laminated structure.
[A29] The light emitting element according to any one of [A23] to [A28], in which the light absorbing material layer has a light absorption coefficient that is 2 times or more the light absorption coefficient of the compound semiconductor constituting the laminated structure.
[A30] The light emitting element according to any one of [A23] to [A29], in which the light absorbing material layer includes at least one type of material selected from the group consisting of a compound semiconductor material having a band gap narrower than that of the compound semiconductor constituting the laminated structure, a compound semiconductor material doped with impurities, a transparent conductive material, and a light reflecting layer constituting material having light absorption characteristics.

### [B01]<<Light Emitting Element Unit>>

A light emitting element unit including a plurality of light emitting elements, in which
each light emitting element includes:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer,
a current confinement region that controls an inflow of a current to the active layer is provided,
when an axis in a thickness direction of the laminated structure passing through a center of a current injection region surrounded by the current confinement region is defined as a Z axis, a direction orthogonal to the Z axis is defined as an X direction, and a direction orthogonal to the X direction and the Z axis is defined as a Y direction, the current injection region has an elongated planar shape in which a longitudinal direction extends in the Y direction, and
the plurality of light emitting elements is arranged apart from each other in the X direction.
   [B02] The light emitting element unit according to [B01], in which, when a width of the current injection region along the Y direction in each light emitting element is L_{max-Y} and a width along the X direction is L_{min-X},

L_{max-Y}/L_{min-X}≥3
is satisfied, and
when an array pitch of the plurality of light emitting elements along the X direction is P_{X},

P_{X}/L_{min-X}≥1.5
is satisfied.
   [B03] The light emitting element unit according to [B01] or [B02], in which,
in the entire light emitting element unit, an emission angle of light in a YZ virtual plane is 2 degrees or less, and
an emission angle of light in an XZ virtual plane is 0.1 degrees or less.
   [B04] The light emitting element unit according to any one of [B01] to [B03], in which
the first electrode is common to the plurality of light emitting elements, and
the second electrode is individually provided in each light emitting element.
   [B05] The light emitting element unit according to any one of [B01] to [B03], in which
the first electrode is common to the plurality of light emitting elements, and
the second electrode is common to the plurality of light emitting elements.

### [C01]<<Electronic Device>>

An electronic device including: the light emitting element according to any one of [A01] to [A30] or the light emitting element unit according to any one of [B01] to [B05].

### [C02]<<Light Emitting Device>>

A light emitting device including: the light emitting element according to any one of [A01] to [A30] or the light emitting element unit according to any one of [B01] to [B05].

### [C03]<<Sensing Device>>

A sensing device including:
a light exit device including the light emitting element according to any one of [A01] to [A30] or the light emitting element unit according to any one of [B01] to [B05]; and
a light receiving device that receives light emitted from the light exit device.

### [C04]<<Communication Device>>

A communication device including:
a light exit device including a plurality of types of the light emitting elements according to [A10] or [A11]; and
a light receiving device that receives light emitted from the light exit device.

### REFERENCE SIGNS LIST

10A, 10B, 10C Light emitting element (surface light emitting element surface light emitting laser element)
11 Compound semiconductor substrate (substrate for manufacturing light emitting element unit)
20 Laminated structure
21 First compound semiconductor layer
21a First surface of first compound semiconductor layer
21b Second surface of first compound semiconductor layer
22 Second compound semiconductor layer
22a First surface of second compound semiconductor layer
22b Second surface of second compound semiconductor layer
23 Active layer (light emitting layer)
26 Light absorbing material layer
31 First electrode
31′ Opening portion provided in first electrode
32 Second electrode
33 Second pad electrode
34 Insulating layer (current confinement layer)
34A Opening portion provided in insulating layer (current confinement layer)
41 First light reflecting layer
42 Second light reflecting layer
48 Bonding layer
49 Support substrate
51 Current injection region
52, 52A, 52B Current confinement region
81, 81′ First sacrificing layer
82 Second sacrificing layer
90 Base surface
90_{bd} Boundary between first part and second part
91 First part of base surface
91′ Convex portion formed in first part of base surface
91a Convex portion formed in first part of base surface
91_{c} Center portion of first part of base surface
92 Second part of base surface
92a Concave portion formed in second part of base surface
92_{c} Center portion of second part of base surface
95 Base material
99 Peripheral region

1: A light emitting element comprising:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer, wherein
a current confinement region that controls an inflow of a current to the active layer is provided, and
when an axis in a thickness direction of the laminated structure passing through a center of a current injection region surrounded by the current confinement region is defined as a Z axis, a direction orthogonal to the Z axis is defined as an X direction, and a direction orthogonal to the X direction and the Z axis is defined as a Y direction, the current injection region has an elongated planar shape in which a longitudinal direction extends in the Y direction.

2: The light emitting element according to claim 1, wherein
when a width of the current injection region along the Y direction is L_{max-Y} and a width along the X direction is L_{min-X},
L_{max-Y}/L_{min-X}≥3
is satisfied.

3: The light emitting element according to claim 1, wherein
the first light reflecting layer has a convex shape toward a direction away from the active layer, and
the second light reflecting layer has a flat shape.

4: The light emitting element according to claim 1, wherein a planar shape of the first light reflecting layer is a shape approximating the planar shape of the current injection region.

5: The light emitting element according to claim 1, wherein an emission angle of light in a YZ virtual plane is 2 degrees or less.

6: The light emitting element according to claim 1, wherein a planar shape of the current injection region is an oval shape.

7: The light emitting element according to claim 1, wherein a planar shape of the current injection region is a rectangular shape.

8: The light emitting element according to claim 7, wherein an end surface including a side parallel to the X direction of the current injection region is in contact with a layer in which a first dielectric layer and a second dielectric layer are alternately arranged in the Y direction.

9: The light emitting element according to claim 6, wherein a side parallel to the Y direction of the current injection region includes a line segment or a curve.

10: A light emitting element comprising:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer, wherein
a current confinement region that controls an inflow of a current to the active layer is provided, and
a planar shape of the current injection region surrounded by the current confinement region includes at least one type of shape selected from a group consisting of an annular shape, a partially cut annular shape, a shape surrounded by a curve, a shape surrounded by a plurality of line segments, and a shape surrounded by a curve and a line segment.

11: The light emitting element according to claim 10, wherein the planar shape of the current injection region includes characters or figures.

12: A light emitting element unit including a plurality of light emitting elements, wherein
each light emitting element includes:
a laminated structure in which
a first compound semiconductor layer having a first surface and a second surface opposing the first surface,
an active layer facing the second surface of the first compound semiconductor layer, and
a second compound semiconductor layer having a first surface facing the active layer and a second surface opposing the first surface are laminated;
a first light reflecting layer formed on the first surface side of the first compound semiconductor layer;
a second light reflecting layer formed on the second surface side of the second compound semiconductor layer;
a first electrode electrically connected to the first compound semiconductor layer; and
a second electrode electrically connected to the second compound semiconductor layer,
a current confinement region that controls an inflow of a current to the active layer is provided,
when an axis in a thickness direction of the laminated structure passing through a center of a current injection region surrounded by the current confinement region is defined as a Z axis, a direction orthogonal to the Z axis is defined as an X direction, and a direction orthogonal to the X direction and the Z axis is defined as a Y direction, the current injection region has an elongated planar shape in which a longitudinal direction extends in the Y direction, and
the plurality of light emitting elements is arranged apart from each other in the X direction.

13: The light emitting element unit according to claim 12, wherein
when a width of the current injection region along the Y direction in each light emitting element is L_{max-Y} and a width along the X direction is L_{min-X},
L_{max-Y}/L_{min-X}≥3
is satisfied, and
when an array pitch of the plurality of light emitting elements along the X direction is P_{X},
P_{X}/L_{min-X}≥1.5
is satisfied.

14: The light emitting element unit according to claim 12, wherein
in the entire light emitting element unit,
an emission angle of light in a YZ virtual plane is 2 degrees or less, and
an emission angle of light in an XZ virtual plane is 0.1 degrees or less.

15: The light emitting element unit according to claim 12, wherein
the first electrode is common to the plurality of light emitting elements, and
the second electrode is individually provided in each light emitting element.

16: The light emitting element unit according to claim 12, wherein
the first electrode is common to the plurality of light emitting elements, and
the second electrode is common to the plurality of light emitting elements.

17: An electronic device comprising the light emitting element unit according to claim 12.

18: A light emitting device comprising the light emitting element unit according to claim 12.

19: A sensing device comprising:
a light exit device including the light emitting element unit according to claim 12; and
a light receiving device that receives light emitted from the light exit device.

20: A communication device comprising:
a light exit device including a plurality of types of the light emitting elements according to claim 10; and
a light receiving device that receives light emitted from the light exit device.
